(19) United States
(12) Patent Application Publication
(10) Pub. No.: US 2023/0387143 A1
(43) Pub. Date: Nov. 30, 2023

(54) DISPLAY DEVICE

(71) Applicant: Samsung Display Co., LTD., Yongin-si (KR)

(72) Inventors: Jong Chan LEE, Yongin-si (KR); Won Tae KIM, Yongin-si (KR); Jin Taek KIM, Yongin-si (KR); Jeong Su PARK, Yongin-si (KR); Woong Hee JEONG, Yongin-si (KR)

(21) Appl. No.: 18/172,218

(22) Filed: Feb. 21, 2023

(30) Foreign Application Priority Data
May 26, 2022 (KR) 10-2022-0064429

(51) Int. Cl. H01L 27/12; H01L 25/16; H01L 33/62

(52) U.S. Cl. CPC H01L 27/1248; H01L 25/167; H01L 33/62

(57) ABSTRACT

A display device includes: a substrate; a via layer on the substrate; a first electrode and a second electrode on the via layer and spaced apart from each other; a first insulating layer on the first electrode and the second electrode; a bank layer on the first insulating layer and having barrier portions and a bank portion having a greater thickness than the barrier portions; a second insulating layer on the bank layer and the first insulating layer, the second insulating layer overlapping the barrier portions and not overlapping the bank portion; light emitting elements on the second insulating layer and on the first electrode and the second electrode; and a first connection electrode contacting an end of each light emitting element and a second connection electrode contacting another end of the light emitting elements.

### CROSS-REFERENCE TO RELATED APPLICATION

This application claims priority to and the benefit of Korean Patent Application No. 10-2022-0064429, filed on May 26, 2022, in the Korean Intellectual Property Office, the disclosure of which is incorporated herein in its entirety by reference.

### BACKGROUND

### 1. Field

Aspects of embodiments of the present disclosure relate to a display device.

### 2. Description of the Related Art

Display devices are becoming increasingly important with the development of multimedia. Accordingly, various types of display devices, such as organic light emitting diode displays (OLEDs) and liquid crystal displays (LCDs), are being used.

A self-luminous display device including a light emitting element is a type of display device for displaying an image. The self-luminous display device may be an organic light emitting display using an organic material as a light emitting material in a light emitting element or an inorganic light emitting display using an inorganic material as a light emitting material.

### SUMMARY

Embodiments of the present disclosure provide a display device that can prevent electrodes from being damaged during a manufacturing process.

However, aspects and features of the present disclosure are not limited to those set forth herein. The above and other aspects and features of the present disclosure will become more apparent to one of ordinary skill in the art to which the present disclosure pertains by referencing the detailed description of the present disclosure given below.

According to an embodiment of the present disclosure, a display device includes a substrate, a via layer on the substrate, a first electrode and a second electrode on the via layer and spaced apart from each other, a first insulating layer on the first electrode and the second electrode, a bank layer on the first insulating layer and having barrier portions and a bank portion having a greater thickness than the barrier portions, a second insulating layer on the bank layer and the first insulating layer, light emitting elements on the second insulating layer and on the first electrode and the second electrode, and a first connection electrode contacting an end of the light emitting elements and a second connection electrode contacting another end of the light emitting elements. The second insulating layer overlaps the barrier portions and does not overlap the bank portion.

In an embodiment, the first insulating layer may be directly disposed on the via layer, the first electrode, and the second electrode.

In an embodiment, a thickness of the first insulating layer may be smaller than a thickness of the second insulating layer.

In an embodiment, the thickness of the first insulating layer may be in a range of about 30% to about 70% of the thickness of the second insulating layer.

In an embodiment, the thickness of the first insulating layer may be in a range of about 500 Å to about 3000 Å.

In an embodiment, the first insulating layer and the second insulating layer may contact each other at an area overlapping the light emitting elements.

In an embodiment, the first insulating layer and the second insulating layer may include the same material.

In an embodiment, the barrier portions may have a first barrier portion overlapping the first electrode and a second barrier portion spaced apart from the first barrier portion and overlapping the second electrode, and the bank portion may extend around a periphery of the first barrier portion and the second barrier portion.

In an embodiment, the bank layer may have a first opening between the first barrier portion and the second barrier portion, and the light emitting elements may be arranged in the first opening.

In an embodiment, the bank layer may separate an emission area in which the light emitting elements are arranged from a sub-area spaced apart from the emission area. A second opening may in the bank layer and spaced apart from the first opening. The first opening may be in the emission area, and the second opening may be in the sub-area.

According to an embodiment of the disclosure, a display device includes a substrate, a via layer on the substrate, a first electrode and a second electrode on the via layer and spaced apart from each other, a first insulating layer on the via layer, the first electrode and the second electrode, a bank layer on the first insulating layer and separating an emission area and a sub-area spaced apart from the emission area, a second insulating layer on the bank layer and the first insulating layer, light emitting elements on the second insulating layer in the emission area and on the first electrode and the second electrode, and a first connection electrode contacting an end of the light emitting elements and a second connection electrode contacting another end of the light emitting elements. The second insulating layer does not overlap areas other than the emission area and the sub-area.

In an embodiment, the bank layer may have barrier portions and a bank portion having a greater thickness than the barrier portions. The barrier portions may overlap the emission area, and the bank portion may not overlap the emission area and the sub-area.

In an embodiment, the second insulating layer may not overlap the bank portion and may overlap the barrier portions.

In an embodiment, the first insulating layer may overlap the bank portion and the barrier portions.

In an embodiment, the barrier portions and the bank portion may be integrally formed.

In an embodiment, the first insulating layer and the second insulating layer may contact each other at an area overlapping the light emitting elements.

In an embodiment, a first contact portion and a second contact portion may penetrate the first insulating layer and the second insulating layer and may be spaced apart from each other in the sub-area. The first connection electrode may be connected to the first electrode through the first contact portion, and the second connection electrode may be connected to the second electrode through the second contact portion.

In an embodiment, the display device may further include a first conductive layer on the substrate and including a bottom metal layer, a first power line, a second power line, and a first pad electrode, a semiconductor layer on the first conductive layer and including an active layer overlapping the bottom metal layer, a second conductive layer on the semiconductor layer and including a source electrode contacting a portion of the semiconductor layer, a drain electrode contacting the first power line, a gate electrode overlapping the semiconductor layer, a first conductive pattern contacting the second power line, and a second pad electrode overlapping the first pad electrode, and a third pad electrode on the second pad electrode.

In an embodiment, the first electrode may be electrically connected to the first power line through the source electrode, and the second electrode may be electrically connected to the second power line through the first conductive pattern.

In an embodiment, the first connection electrode, the second connection electrode, and the third pad electrode may include the same material.

In a display device according to an embodiment, a first insulating layer may completely cover electrodes to prevent a developer in a subsequent process from reaching the electrodes, thereby preventing lifting or breaking of the electrodes.

However, the aspects and features of the present disclosure are not limited to those set forth herein. The above and other aspects and features of the present disclosure will become more apparent to one of ordinary skill in the art to which the present disclosure pertains by referencing the following detailed description and the claims.

### BRIEF DESCRIPTION OF THE DRAWINGS

These and/or other aspects and features will become apparent and more readily appreciated from the following description of the embodiments, taken in conjunction with the accompanying drawings, in which:

FIG. 1 is a schematic plan view of a display device according to an embodiment;

FIG. 2 is a plan view illustrating the arrangement of a plurality of wirings included in the display device according to the embodiment;

FIG. 3 is an equivalent circuit diagram of a subpixel according to an embodiment;

FIG. 4 is a plan view of a pixel of the display device according to an embodiment;

FIG. 5 is a cross-sectional view of a pad portion and a cross-sectional view taken along the line E1-E1′ of FIG. 4;

FIG. 6 is a cross-sectional view taken along the line E2-E2′ of FIG. 4;

FIG. 7 is a plan view of a first insulating layer disposed in a subpixel;

FIG. 8 is a plan view of a bank layer disposed in the subpixel;

FIG. 9 is a plan view of a second insulating layer disposed in the subpixel;

FIG. 10 is an enlarged view of the area A of FIG. 5;

FIG. 11 is a schematic view of a light emitting element according to an embodiment;

FIGS. 12 through 22 are cross-sectional views sequentially illustrating steps of a process of manufacturing a display device according to an embodiment; and

FIG. 23 is a cross-sectional view of a subpixel and a pad portion of a display device according to an embodiment.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that this disclosure will be thorough and complete, and will filly convey the scope of the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof. Each of the features of the various embodiments of the present disclosure may be combined or combined with each other, in part or in whole, and technically various interlocking and driving are possible. Each embodiment may be implemented independently of each other or may be implemented together in an association. Hereinafter, embodiments of the present disclosure will be described with reference to the accompanying drawings.

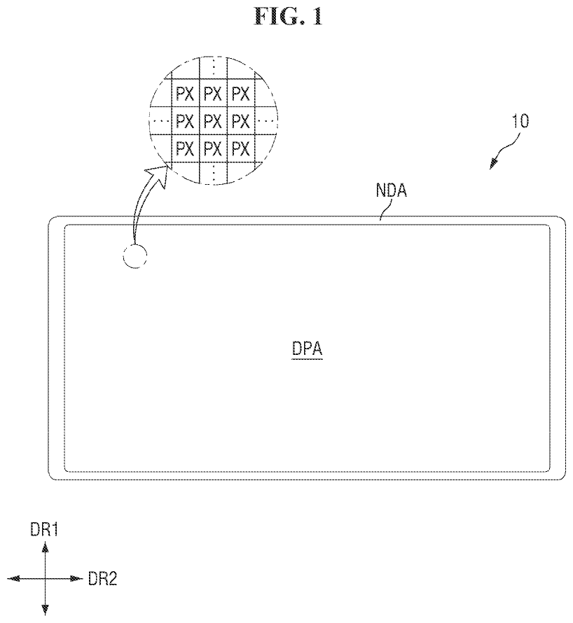

FIG. 1 is a schematic plan view of a display device 10 according to an embodiment.

Referring to FIG. 1, the display device 10 is configured to display moving images and/or still images. The display device 10 may refer to any electronic device that provides a display screen. Examples of the display device 10 may include a television, a notebook computer, a monitor, a billboard, an Internet of Things (IoT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game console, a digital camera and a camcorder, all of which provide a display screen.

The display device 10 includes a display panel that provides a display screen. Examples of the display panel include an inorganic light emitting diode display panel, an organic light emitting diode display panel, a quantum dot light emitting display panel, a plasma display panel, and a field emission display panel. The display panel will be described as an inorganic light emitting diode display panel below, but the present disclosure is not limited thereto, and other display panels can also be applied as long as the same technical spirit is applicable.

The shape of the display device 10 can be variously modified. For example, the display device 10 may have various shapes, such as a horizontally long rectangle, a vertically long rectangle, a square, a quadrilateral with rounded corners (e.g., vertices), other polygons, or a circle. The shape of a display area DPA of the display device 10 may be similar to the overall shape of the display device 10. In FIG. 1, the display device 10 is shaped like a rectangle that is long in a second direction DR2.

The display device 10 may have the display area DPA and a non-display area NDA. The display area DPA may be an area where an image can be displayed, and the non-display area NDA may be an area where no image is displayed. The display area DPA may also be referred to as an active area, and the non-display area NDA may also be referred to as an inactive area. The display area DPA may generally occupy a center of the display device 10.

The display area DPA may include a plurality of pixels PX. The pixels PX may be arranged in a matrix. Each of the pixels PX may be rectangular or square in a plan view. However, the present disclosure is not limited thereto, and each of the pixels PX may also have a rhombic planar shape in which each side is inclined with respect to a direction (e.g., with respect to an arrangement direction). The pixels PX may be arranged in a stripe or island type. In addition, each of the pixels PX may include one or more light emitting elements that are configured to emit light of a specific wavelength band to display a specific color.

The non-display area NDA may be located around the display area DPA. The non-display area NDA may entirely or partially surround (e.g., surround in a plan view or extend around a periphery of) the display area DPA. The display area DPA may be rectangular, and the non-display area NDA may be disposed adjacent to four sides of the display area DPA. The non-display area NDA may form a bezel of the display device 10. Wirings or circuit drivers included in the display device 10 may be located, or external devices may be mounted, in each non-display area NDA.

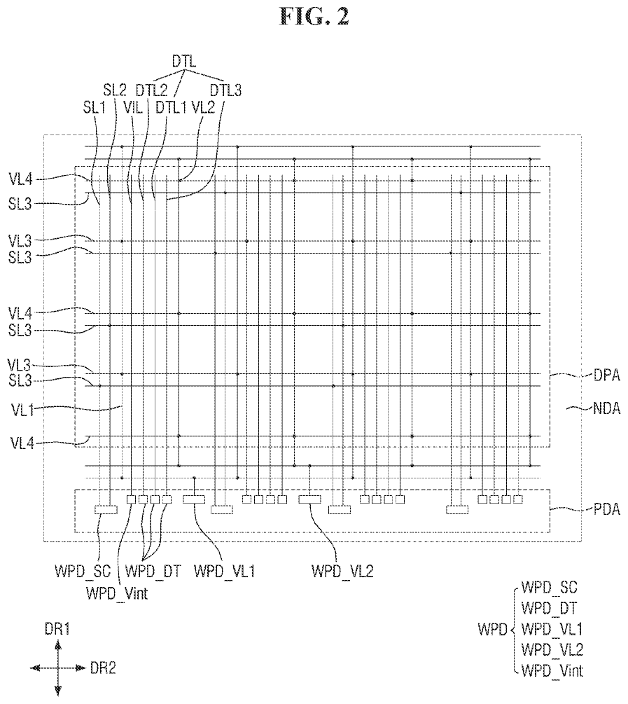

FIG. 2 is a plan view illustrating the arrangement of a plurality of wirings included in the display device 10 according to an embodiment.

Referring to FIG. 2, the display device 10 may include a plurality of wirings. The display device 10 may include a plurality of scan lines SL (e.g., SL1 through SL3), a plurality of data lines DTL (e.g., DTL1 through DTL3), initialization voltage wirings VIL, and a plurality of voltage wirings VL (e.g., VL1 through VL4). Other wirings may be further disposed in the display device 10.

First scan lines SL1 and second scan lines SL2 may extend in a first direction DR1. A first scan line SL1 and a second scan line SL2 may be disposed adjacent to each other and may be spaced apart from other first scan lines SL1 and other second scan lines SL2 in the second direction DR2. The first and second scan lines SL1 and SL2 may be connected to each scan wiring pad WPD_SC connected to a scan driver (e.g., each pair of first and second scan lines SL1 and SL2 may be connected to the same wiring pad WPD_SC). The first scan lines SL1 and the second scan lines SL2 may extend from a pad area PDA in the non-display area NDA to the display area DPA.

Each third scan line SL3 may extend in the second direction DR2 and may be spaced apart from other third scan lines SL3 in the first direction DR1. One third scan line SL3 may be connected to one or more first scan lines SL1 or one or more second scan lines SL2. In an embodiment, the first scan lines SL1 and the second scan lines SL2 may be made of a conductive layer disposed on a different layer than the third scan lines SL3. The scan lines SL may have a mesh structure in (or over) the entire display area DPA, but the present disclosure is not limited thereto.

In the present specification, the term “connect” may mean that any one member and another member are connected to each other not only through physical contact but also through another member. In addition, it can be understood that any one part and another part are connected to each other as one integrated member. Further, the connection between any one member and another member can be interpreted to include electrical connection through another member in addition to connection through direct contact.

The data lines DTL may extend in the first direction DR1. The data lines DTL may include first data lines DTL1, second data lines DTL2, and third data lines DTL3. One of each of the first through third data lines DTL1 through DTL3 may form one group and may be disposed adjacent to each other. The data lines DTL1 through DTL3 may extend from the pad area PDA in the non-display area NDA to the display area DPA. However, the present disclosure is not limited thereto, and the data lines DTL may also be disposed at equal intervals between first and second voltage wirings VL1 and VL2, to be described later.

The initialization voltage wirings VIL may extend in the first direction DR1. Each of the initialization voltage wirings VIL may be disposed between the data lines DTL and the first and second scan lines SL1 and SL2. The initialization voltage wirings VIL may extend from the pad area PDA in the non-display area NDA to the display area DPA.

The first voltage wirings VL1 and the second voltage wirings VL2 extend in the first direction DR1, and third voltage wirings VL3 and fourth voltage wirings VL4 extend in the second direction DR2. The first voltage wirings VL1 and the second voltage wirings VL2 may be alternately disposed in the second direction DR2, and the third voltage wirings VL3 and the fourth voltage wirings VL4 may be alternately disposed in the first direction DR1. The first voltage wirings VL1 and the second voltage wirings VL2 may extend in the first direction DR1 to cross the display area DPA. From among the third voltage wirings VL3 and the fourth voltage wirings VL4, some wirings may be disposed in the display area DPA and other wirings may be disposed in the non-display area NDA located at both sides of the display area DPA in the first direction DR1. The first voltage wirings VL1 and the second voltage wirings VL2 may be made of a conductive layer disposed on a different layer than the third voltage wirings VL3 and the fourth voltage wirings VL4. Each of the first voltage wirings VL1 may be connected to at least one third voltage wiring VL3, and each of the second voltage wirings VL2 may be connected to at least one fourth voltage wiring VL4. Therefore, the voltage wirings VL may have a mesh structure in (or over) the entire display area DPA. However, the present disclosure is not limited thereto. The first scan lines SL1, the second scan lines SL2, the data lines DTL, the initialization voltage wirings VIL, the first voltage wirings VL1, and the second voltage wirings VL2 may be electrically connected to at least one wiring pad WPD. Each wiring pad WPD may be disposed in the non-display area NDA. In an embodiment, each wiring pad WPD may be disposed in the pad area PDA located at a lower side (e.g., a lower side in the drawing) of the display area DPA, which is a second side in the first direction DR1. The first and second scan lines SL1 and SL2 are connected to each scan wiring pad WPD_SC disposed in the pad area PDA, and the data lines DTL are connected to different data wiring pads WPD_DT, respectively. Each of the initialization voltage wirings VIL is connected to an initialization wiring pad WPD_Vint, the first voltage wirings VL1 are connected to a first voltage wiring pad WPD_VL1, and the second voltage wirings VL2 are connected to a second voltage wiring pad WPD_VL2. An external device may be mounted on the wiring pads WPD. The external device may be mounted on the wiring pads WPD via an anisotropic conductive film, ultrasonic bonding, or the like. Although each wiring pad WPD is disposed in the pad area PDA located at the lower side of the display area DPA in the drawing, the present disclosure is not limited thereto. Some of the wiring pads WPD may also be disposed in an area located at an upper side or any one of left and right sides of the display area DPA.

Each pixel PX or subpixel SPXn (n is an integer of 1 to 3) of the display device 10 includes a pixel driving circuit. The above-described wirings may transmit driving signals to each pixel driving circuit while passing through, by, or around each pixel PX. The pixel driving circuit may include a transistor and a capacitor. The number of transistors and capacitors in each pixel driving circuit can be variously changed. According to an embodiment, each subpixel SPXn of the display device 10 may have a 3T1C structure in which the pixel driving circuit includes three transistors and one capacitor. Although the pixel driving circuit will be described below using the 3T1C structure as an example, the present disclosure is not limited thereto, and other various structures, such as a 2T1C structure, a 7T1C structure, and a 6T1C structure are applicable.

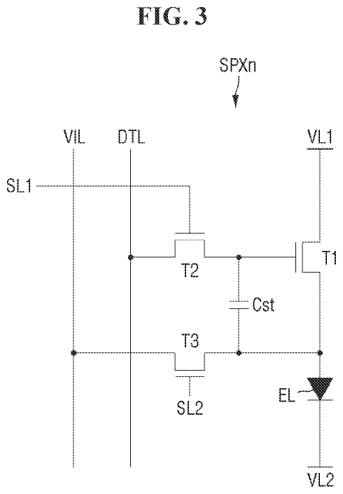

FIG. 3 is an equivalent circuit diagram of a subpixel SPXn according to an embodiment.

Referring to FIG. 3, each subpixel SPXn of the display device 10, according to an embodiment, includes three transistors T1 through T3 and one storage capacitor Cst in addition to a light emitting diode EL.

The light emitting diode EL emits light according to a current supplied through a first transistor T1. The light emitting diode EL includes a first electrode, a second electrode, and at least one light emitting element disposed between them. The light emitting element may emit light of a specific wavelength band in response to electrical signals received from the first electrode and the second electrode.

A first end of the light emitting diode EL may be connected to a source electrode of the first transistor T1, and a second end of the light emitting diode EL may be connected to a second voltage wiring VL2 to which a low potential voltage (hereinafter, referred to as a second power supply voltage) lower than a high potential voltage (hereinafter, referred to as a first power supply voltage) of a first voltage wiring VL1 is supplied.

The first transistor T1 adjusts a current flowing from the first voltage wiring VL1, to which the first power supply voltage is supplied, to the light emitting diode EL according to a voltage difference between a gate electrode and the source electrode. For example, the first transistor T1 may be a driving transistor for driving the light emitting diode EL. The gate electrode of the first transistor T1 may be connected to a source electrode of a second transistor T2, the source electrode of the first transistor T1 may be connected to the first electrode of the light emitting diode EL, and a drain electrode of the first transistor T1 may be connected to the first voltage wiring VL1 to which the first power supply voltage is applied.

The second transistor T2 is turned on by a scan signal of a first scan line SL1 to connect a data line DTL to the gate electrode of the first transistor T1. A gate electrode of the second transistor T2 may be connected to the first scan line SL1, the source electrode of the second transistor T2 may be connected to the gate electrode of the first transistor T1, and a drain electrode of the second transistor T2 may be connected to the data line DTL.

A third transistor T3 is turned on by a scan signal of a second scan line SL2 to connect an initialization voltage wiring VIL to the first end of the light emitting diode EL. A gate electrode of the third transistor T3 may be connected to the second scan line SL2, a drain electrode of the third transistor T3 may be connected to the initialization voltage wiring VIL, and a source electrode of the third transistor T3 may be connected to the first end of the light emitting diode EL or the source electrode of the first transistor T1.

In an embodiment, the source electrode and the drain electrode of each of the transistors T1 through T3 are not limited to the above description, and the opposite may also be the case. In addition, each of the transistors T1 through T3 may be formed as a thin-film transistor. In addition, although each of the transistors T1 through T3 is primarily described as being an N-type metal oxide semiconductor field effect transistor (MOSFET) in FIG. 3, the present disclosure is not limited thereto. For example, each of the transistors T1 through T3 may also be formed as a P-type MOSFET, or some of the transistors T1 through T3 may be formed as N-type MOSFETs and the other may be formed as a P-type MOSFET.

The storage capacitor Cst is formed between the gate electrode and the source electrode of the first transistor T1. The storage capacitor Cst stores a difference between a gate voltage and a source voltage of the first transistor T1.

The structure of a pixel PX of the display device 10 according to an embodiment will now be described in detail with further reference to other drawings.

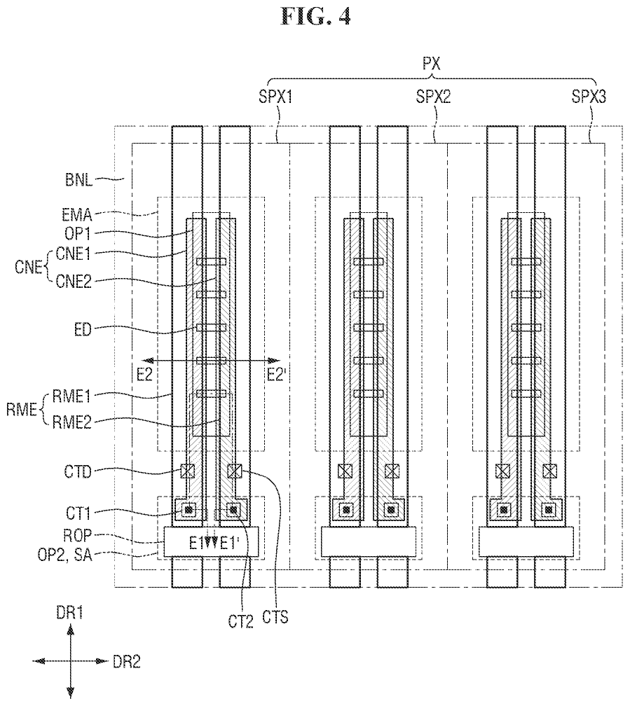

FIG. 4 is a plan view of a pixel PX of the display device 10 according to an embodiment.

FIG. 4 illustrates the planar arrangement of electrodes RME (e.g., RME1 and RME2), a bank layer BNL, a plurality of light emitting elements ED, and connection electrodes CNE (e.g., CNE1 and CNE2) in a pixel PX of the display device 10.

Referring to FIG. 4, each of the pixels PX of the display device 10 may include a plurality of subpixels SPXn. For example, one pixel PX may include a first subpixel SPX1, a second subpixel SPX2, and a third subpixel SPX3. The first subpixel SPX1 may emit light of a first color, the second subpixel SPX2 may emit light of a second color, and the third subpixel SPX3 may emit light of a third color. For example, the first color may be blue, the second color may be green, and the third color may be red. However, the present disclosure is not limited thereto, and the subpixels SPXn may also emit light of the same color. In an embodiment, the subpixels SPXn may emit blue light. Although one pixel PX includes three subpixels SPXn in the drawing, the present disclosure is not limited thereto, and the pixel PX may include a greater number of subpixels SPXn.

Each subpixel SPXn of the display device 10 may have an emission area EMA and a non-emission area. The emission area EMA may be an area in which the light emitting elements ED are disposed to emit light of a specific wavelength band. The non-emission area may be an area in which the light emitting elements ED are not disposed and from which no light is output because light emitted from the light emitting elements ED does not reach this area.

The emission area EMA may include an area in which the light emitting elements ED are disposed and an area adjacent to the light emitting elements ED and from which light emitted from the light emitting elements ED is output. For example, the emission area EMA may also include an area from which light emitted from the light emitting elements ED is output after being reflected or refracted by other members. A plurality of light emitting elements ED may be disposed in each subpixel SPXn, and an area where the light emitting elements ED are located and an area adjacent to this area may form the emission area EMA.

Although the respective emission areas EMA of the subpixels SPXn have substantially the same area in the drawing, the present disclosure is not limited thereto. In some embodiments, the emission area EMA of the subpixels SPXn may have a different area according to the color or wavelength band of light emitted from the light emitting elements ED disposed in the subpixel SPXn.

Each subpixel SPXn may further include a sub-area SA in the non-emission area. The sub-area SA of each subpixel SPXn may be disposed at a lower side (e.g., in the drawings) of the emission area EMA, which is the second side in the first direction DR1. The emission area EMA and the sub-area SA may be alternately arranged along the first direction DR1, and the sub-area SA may be disposed between the emission areas EMA of different subpixels SPXn that are spaced apart from each other in the first direction DR1. For example, the emission area EMA and the sub-area SA may be alternately arranged in the first direction DR1 and may each be repeatedly arranged in the second direction DR2. However, the present disclosure is not limited thereto, and the arrangement of the emission areas EMA and the sub-areas SA in a plurality of pixels PX may be different from that in FIG. 4.

Light may not exit from (or may not be emitted from) the sub-area SA because the light emitting elements ED are not disposed in the sub-area SA, but a portion of each of the electrodes RME disposed in each subpixel SPXn may be disposed in the sub-area SA. The electrodes RME disposed in different subpixels SPXn may be separated from each other at a separation portion ROP of the sub-area SA.

The display device 10 may include the electrodes RME (e.g., RME1 and RME2), the bank layer BNL, the light emitting elements ED, and the connection electrodes CNE (e.g., CNE1 and CNE2).

The electrodes RME extend in one direction and are disposed in each subpixel SPXn. The electrodes RME may extend in the first direction DR1 to lie in the emission area EMA and the sub-area SA of each subpixel SPXn and may be spaced apart from each other in the second direction DR2. The electrodes RME may be electrically connected to the light emitting elements ED, to be described later. However, the present disclosure is not limited thereto, and the electrodes RME may not be electrically connected to the light emitting elements ED.

The electrodes RME may include a first electrode RME1 and a second electrode RME2 disposed in each subpixel SPXn. The first electrode RME1 is disposed on a left side of a center of the emission area EMA, and the second electrode RME2 is spaced apart from the first electrode RME1 in the second direction DR2 and is disposed on a right side of the center of the emission area EMA. The first electrodes RME1 and the second electrodes RME2 of different subpixels SPXn may be spaced apart from each other by the separation portion ROP located in the sub-area SA of any one subpixel SPXn.

Although two electrodes RME extend in the first direction DR1 in each subpixel SPXn in the drawing, the present disclosure is not limited thereto. For example, in the display device 10, a greater number of the electrodes RME may be disposed in one subpixel SPXn, or the electrodes RME may be partially bent and may have a different width according to position.

The bank layer BNL may be disposed over the entire display area DPA and may partially expose or surround (e.g., surround in a plan view or extend around a periphery of) the subpixels SPXn. The bank layer BNL may have a first opening OP1 and a second opening OP2 spaced apart from the first opening OP1. The first opening OP1 may be disposed in the emission area EMA of each subpixel SPXn, and the second opening OP2 may be disposed in the sub-area SA located on a side of the emission area EMA. The sub-area SA may be defined as the second opening OP2 in the bank layer BNL.

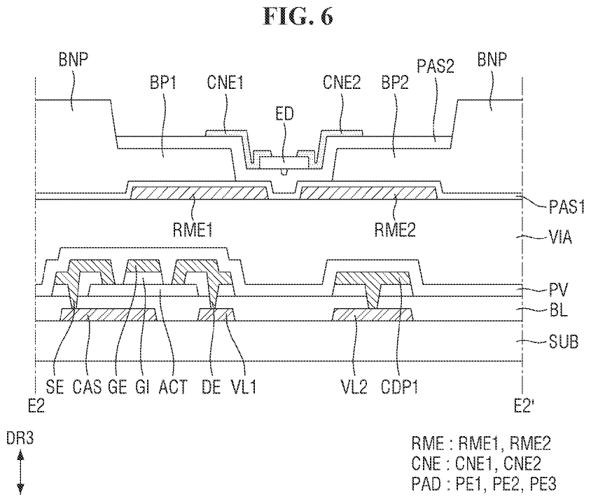

As will be described later, the bank layer BNL may include a bank portion BNP (see, e.g., FIG. 6) and barrier portions BP1 and BP2 (see, e.g., FIG. 6) having a lower height than the bank portion BNP.

The bank portion BNP may be disposed at boundaries between the subpixels SPXn adjacent to each other in the first direction DR1 and the second direction DR2 and may also be disposed at boundaries between the emission areas EMA and the sub-areas SA. The subpixels SPXn, the emission areas EMA, and the sub-areas SA of the display device 10 may be areas separated by the bank portion BNP. Distances between the subpixels SPXn, the emission areas EMA, and the sub-areas SA may vary according to a width of the bank portion BNP. The bank portion BNP may overlap the boundaries of the subpixels SPXn, the sub-areas SA, and the electrodes RME between the emission areas EMA and the sub-areas SA.

The bank portion BNP of the bank layer BNL may also be disposed in the sub-area SA of each subpixel SPXn. The bank portion BNP may surround (e.g., surround in a plan view or extend around a periphery of) the second opening OP2 disposed in the sub-area SA. The second opening OP2 formed by the bank portion BNP may be the same as the separation portion ROP, and the electrodes RME and the connection electrode CNE are not disposed in the second opening OP2.

The barrier portions BP1 and BP2 of the bank layer BNL may be integrated with the bank portion BNP and disposed in the emission area EMA of each subpixel SPXn. The barrier portions BP1 and BP2 may be spaced apart from each other with the first opening OP1 in the emission area EMA interposed between them. The light emitting elements ED may be disposed in the first opening OP1 formed by the barrier portions BP1 and BP2. The barrier portions BP1 and BP2 may respectively overlap the electrodes RME1 and RME2 in the emission area EMA of each subpixel SPXn.

The light emitting elements ED may be disposed in the emission area EMA. The light emitting elements ED may be disposed in the first opening OP1 in the bank layer BNL and may be spaced apart from each other in the first direction DR1. In an embodiment, the light emitting elements ED may extend in a direction, and both ends (e.g., opposite ends) of the light emitting elements ED may be disposed on different electrodes RME, respectively. For example, first ends of the light emitting elements ED may be disposed on the first electrode RME1, and second ends of the light emitting elements ED may be disposed on the second electrode RME2. A length of each light emitting element ED may be greater than a distance between the electrodes RME spaced apart in the second direction DR2. The direction in which the light emitting elements ED extend may be substantially perpendicular to the first direction DR1 in which the electrodes RME extend. However, the present disclosure is not limited thereto, and the direction in which the light emitting elements ED extend may be the second direction DR2 or a direction oblique to the second direction DR2.

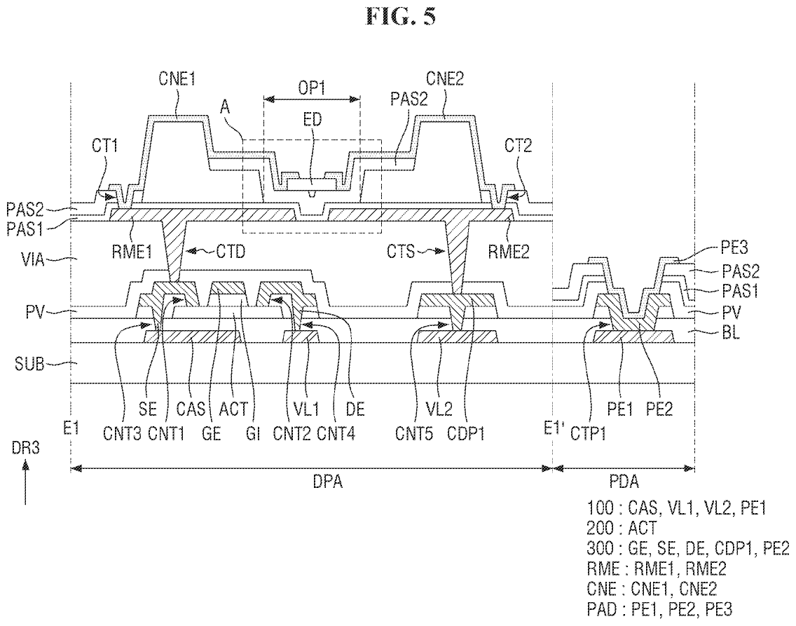

The connection electrodes CNE may be disposed on the light emitting elements ED, a second insulating layer PAS2 (see, e.g., FIG. 5), and the bank layer BNL. The connection electrodes CNE may extend in a direction and may be spaced apart from each other. Each of the connection electrodes CNE may contact the light emitting elements ED and may be electrically connected to an electrode RME.

The connection electrodes CNE may include a first connection electrode CNE1 and a second connection electrode CNE2 disposed in each subpixel SPXn. The first connection electrode CNE1 may extend in the first direction DR1 and may be disposed on the first electrode RME1. The first connection electrode CNE1 may partially overlap the first electrode RME1 and may extend from the emission area EMA to the sub-area SA. The second connection electrode CNE2 may extend in the first direction DR1 and may be disposed on the second electrode RME2. The second connection electrode CNE2 may partially overlap the second electrode RME2 and may extend from the emission area EMA to the sub-area SA. The first connection electrode CNE1 may contact the first ends of the light emitting elements ED, and the second connection electrode CNE2 may contact the second ends of the light emitting elements ED.

According to an embodiment, in the display device 10, the connection electrodes CNE may respectively contact the electrodes RME through contact portions CT1 and CT2 disposed in the sub-area SA. The first connection electrode CNE1 may contact the first electrode RME1 through a first contact portion CT1 in the sub-area SA. The second connection electrode CNE2 may contact the second electrode RME2 through a second contact portion CT2 in the sub-area SA. Power supply voltages may be applied to the connection electrodes CNE through the electrodes RME, respectively. A first power supply voltage may be applied to the first connection electrode CNE1 through the first electrode RME1, and a second power supply voltage may be applied to the second connection electrode CNE2 through the second electrode RME2. Each connection electrode CNE may contact the light emitting elements ED in the emission area EMA to transmit a power supply voltage to the light emitting elements ED.

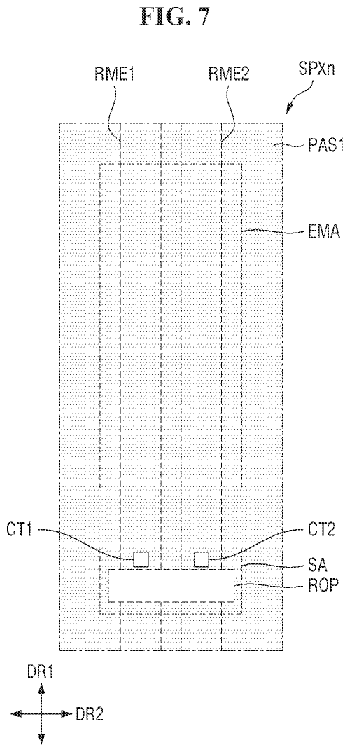

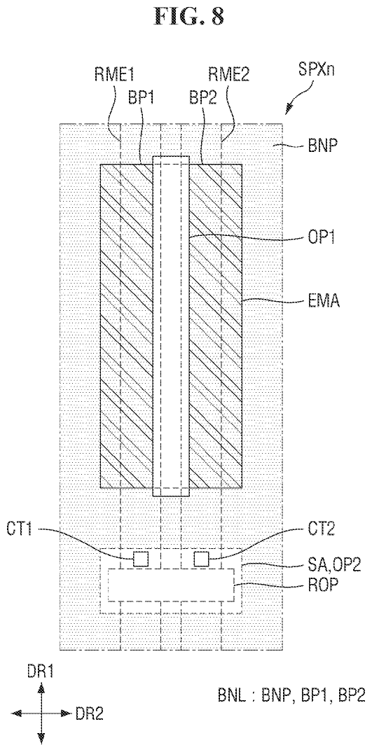

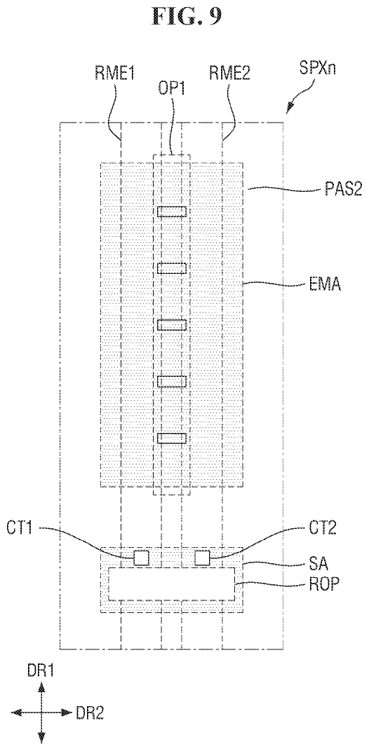

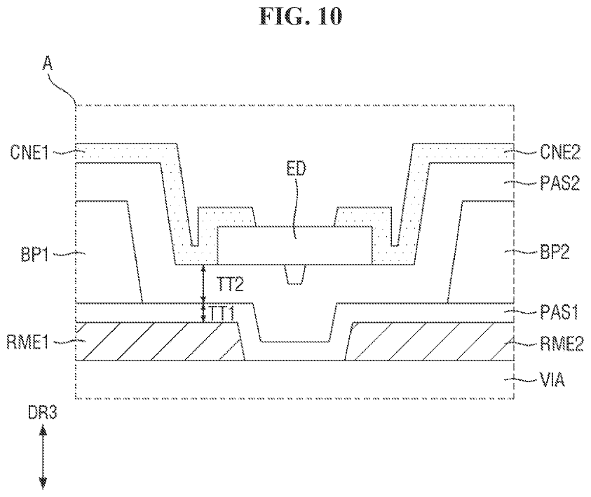

FIG. 5 is a cross-sectional view of a pad portion and a cross-sectional view taken along the line E1-E1′ of FIG. 4. FIG. 6 is a cross-sectional view taken along the line E2-E2′ of FIG. 4. FIG. 7 is a plan view of a first insulating layer PAS1 disposed in a subpixel SPXn. FIG. 8 is a plan view of the bank layer BNL disposed in the subpixel SPXn. FIG. 9 is a plan view of the second insulating layer PAS2 disposed in the subpixel SPXn. FIG. 10 is an enlarged view of the area A of FIG. 5.

FIG. 5 illustrates a cross section across both ends of a light emitting element ED, electrode contact holes (e.g., electrode contact openings) CTD and CTS, and the contact portions CT1 and CT2 disposed in the first subpixel SPX1 and a cross section of the pad portion. FIG. 6 illustrates a cross section across both ends of a light emitting element ED and a portion of the bank layer BNL disposed in the first subpixel SPX1. FIG. 7 illustrates the planar arrangement of the first insulating layer PAS1 disposed under the bank layer BNL. FIG. 8 illustrates the planar arrangement of the bank layer BNL disposed under the second insulating layer PAS2. FIG. 9 illustrates the planar arrangement of the second insulating layer PAS2.

Referring to FIGS. 5 through 10, the display device 10 may include a substrate SUB and a semiconductor layer, a plurality of conductive layers, and a plurality of insulating layers disposed on the substrate SUB. In addition, the display device 10 may include the electrodes RME, the light emitting elements ED, and the connection electrodes CNE. The semiconductor layer, the conductive layers, and the insulating layers may form a circuit element layer and a display element layer of the display device 10.

The substrate SUB may be an insulating substrate. The substrate SUB may be made of an insulating material, such as glass, quartz, or polymer resin. In addition, the substrate SUB may be a rigid substrate, but in other embodiments, may be a flexible substrate that can be bent, folded, rolled, etc.

The circuit element layer may be disposed on the substrate SUB. The circuit element layer may include a first conductive layer 100, a buffer layer BL, a semiconductor layer 200, a gate insulating layer GI, a second conductive layer 300, a passivation layer PV, and a via layer VIA.

The first conductive layer 100 is disposed on the substrate SUB. The first conductive layer 100 may include a first voltage wiring VL1, a second voltage wiring VL2, a bottom metal layer CAS, and a first pad electrode PE1. The first voltage wiring VL1, the second voltage wiring VL2, and the bottom metal layer CAS disposed in the display area DPA and the first pad electrode PE1 disposed in the pad area PDA may be made of the first conductive layer 100. The first conductive layer 100 may further include a data line DTL (see, e.g., FIG. 3) described above, an initialization voltage wiring VIL (see, e.g., FIG. 3), or a scan line SL (see, e.g., FIG. 3) extending in the second direction DR2.

The first voltage wiring VL1 may overlap at least a portion of a drain electrode DE of a transistor, to be described later, in a thickness direction of the substrate SUB. The first voltage wiring VL1 may be electrically connected to the drain electrode DE of the transistor through a fourth contact hole (e.g., a fourth contact opening) CNT4. A high potential voltage (e.g., a first power supply voltage) supplied to the transistor may be applied to the first voltage wiring VL1.

The second voltage wiring VL2 may overlap at least a portion of a first conductive pattern CDP1 in the thickness direction of the substrate SUB. The second voltage wiring VL2 may be electrically connected to the first conductive pattern CDP1 through a fifth contact hole (e.g., a fifth contact opening) CNT5. A low potential voltage (e.g., a second power supply voltage) lower than the high potential voltage supplied to the first voltage wiring VL1 may be applied to the second voltage wiring VL2. The high potential voltage supplied to the transistor may be applied to the first voltage wiring VL1, and the low potential voltage that is lower than the high potential voltage supplied to the first voltage wiring VL1 may be applied to the second voltage wiring VL2.

The bottom metal layer CAS may be disposed under an active layer ACT of the transistor to cover at least a channel region of the active layer ACT. The bottom metal layer CAS may be a light blocking layer that protects the active layer ACT of the transistor from external light. In addition, the bottom metal layer CAS may be electrically connected to the active layer ACT to stabilize electrical characteristics of the transistor. However, the present disclosure is not limited thereto, and the bottom metal layer CAS may be omitted in some embodiments.

The first pad electrode PE1 may be any one of the pads WPD of the wirings

described above. For example, the first pad electrode PE1 may be a first pad electrode PE of any one of the scan wiring pads WPD_SC, the data wiring pads WPD_DT, the initialization wiring pads WPD_Vint, the first voltage wiring pad WPD_VL1, and the second voltage wiring pad WPD_VL2.

The first conductive layer 100 may be made of a light-blocking material, that is, an opaque metal material that blocks or substantially blocks transmission of light. In some embodiments, the first conductive layer 100 may be, but is not limited to, a single layer or a multilayer structure made of any one or more selected from molybdenum (Mo), aluminum (Al), chromium (Cr), gold (Au), titanium (Ti), nickel (Ni), neodymium (Nd), copper (Cu), and alloys thereof. For example, the first conductive layer 100 may be a Ti/Cu double layer in which a titanium layer and a copper layer are stacked.

The buffer layer BL may be disposed on the first conductive layer 100 and the substrate SUB. The buffer layer BL may be disposed in the display area DPA and the pad area PDA of the non-display area NDA (see, e.g., FIG. 1). The buffer layer BL may have a third contact hole (e.g., a third contact opening) CNT3 and the fourth contact hole (e.g., a fourth contact opening) CNT4, which partially expose the first conductive layer 100 together with the gate insulating layer GI in the display area DPA. A first pad contact hole (e.g., a first pad contact opening) CTP1 may extend through the buffer layer BL and the gate insulating layer GI in the pad area PDA.

The buffer layer BL may protect a plurality of transistors from moisture introduced through the substrate SUB, which may be vulnerable to moisture penetration. In some embodiments, the buffer layer BL may include, but is not limited to, an inorganic insulating material, such as silicon oxide (SiOₓ), silicon nitride (SiNₓ), or silicon oxynitride (SiOₓN_{y}).

The semiconductor layer 200 may be disposed on the buffer layer BL. The semiconductor layer 200 may include the active layer ACT of the transistor disposed in the display area DPA. The active layer ACT of the transistor may overlap the bottom metal layer CAS as described above.

The semiconductor layer 200 may include polycrystalline silicon, monocrystalline silicon, an oxide semiconductor, or the like. In an embodiment, the semiconductor layer 200 may include polycrystalline silicon or an oxide semiconductor. The oxide semiconductor may include indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

The gate insulating layer GI may be disposed on the buffer layer BL, on which the semiconductor layer 200 is disposed. The gate insulating layer GI may be formed in the same pattern as the second conductive layer 300, to be described later. In some embodiments, side surfaces of the gate insulating layer GI may be aligned or substantially aligned with side surfaces of the second conductive layer 300, but the present disclosure is not limited thereto. The gate insulating layer GI may be a single layer made of an inorganic layer including at least any one of inorganic materials, such as silicon oxide (SiOₓ), silicon nitride (SiNₓ) and silicon oxynitride (SiOₓN_{y}), or may be a multilayer structure in which inorganic layers are alternately stacked.

The second conductive layer 300 may be disposed on the gate insulating layer GI. The second conductive layer 300 may include a gate electrode GE, the drain electrode DE, and a source electrode SE of the transistor disposed in the display area DPA, the first conductive pattern CDP1, and a second pad electrode PE2.

The gate electrode GE may overlap the channel region of the active layer ACT in a third direction DR3, which is the thickness direction of the substrate SUB. The second conductive layer 300 may further include an electrode of a storage capacitor.

The drain electrode DE may be spaced apart from the gate electrode GE. The drain electrode DE may be electrically connected to a portion of the active layer ACT by contacting the portion of the active layer ACT through a second contact hole (e.g., a second contact opening) CNT2 penetrating the gate insulating layer GI to expose the portion of the active layer ACT. In addition, the drain electrode DE may be electrically connected to the first voltage wiring VL1 by contacting the first voltage wiring VL1 through the fourth contact hole CNT4 penetrating the gate insulating layer GI and the buffer layer BL to expose a portion of the first voltage wiring VL1. A portion of the active layer ACT may be electrically connected to the first voltage wiring VL1 through the drain electrode DE.

The source electrode SE may be spaced apart from the drain electrode DE and the gate electrode GE. The source electrode SE may be electrically connected to another portion of the active layer ACT by contacting the portion of the active layer ACT through a first contact hole (e.g., a first contact opening) CNT1 penetrating the gate insulating layer GI to expose the portion of the active layer ACT. The source electrode SE may also be electrically connected to the bottom metal layer CAS by contacting the bottom metal layer CAS disposed under the source electrode SE through the third contact hole CNT3 penetrating the gate insulating layer GI and the buffer layer BL.

The first conductive pattern CDP1 may overlap the second voltage wiring VL2. The first conductive pattern CDP1 may be electrically connected to the second voltage wiring VL2 by contacting the second voltage wiring VL2 through the fifth contact hole CNT5 penetrating the gate insulating layer GI and the buffer layer BL to expose a portion of the second voltage wiring VL2. The first conductive pattern CDP1 may be a connection pattern that electrically connects the second voltage wiring VL2, made of the first conductive layer 100, to the second electrode RME2, to be described later.

The second pad electrode PE2 may be disposed in the pad area PDA of the non-display area NDA. The second pad electrode PE2 may be disposed on the gate insulating layer GI. The second pad electrode PE2 may overlap the first pad electrode PE1 in the third direction DR3. The second pad electrode PE2 may have substantially the same width as the first pad electrode PE1, but the present disclosure is not limited thereto. The second pad electrode PE2 may be electrically connected to the first pad electrode PE1 through the first pad contact hole CTP1 penetrating the gate insulating layer GI and the buffer layer BL to expose a portion of the first pad electrode PE1.

As will be described later, the first contact hole CNT1, the second contact hole CNT2, the third contact hole CNT3, the fourth contact hole CNT4, and the first pad contact hole CTP1 penetrating the buffer layer BL and the gate insulating layer GI may be contact holes (e.g., contact opening) concurrently (or simultaneously) formed through a single mask process.

The second conductive layer 300 may be a single layer or a multilayer structure made of any one or more selected from molybdenum (Mo), aluminum (Al), chromium (Cr), gold (Au), titanium (Ti), nickel (Ni), neodymium (Nd), copper (Cu), and alloys thereof.

The passivation layer PV may be disposed on the buffer layer BL on which the second conductive layer 300 is formed. The passivation layer PV may cover and protect the second conductive layer 300. For example, the passivation layer PV may be disposed on the second pad electrode PE2 of the pad area PDA to protect the second pad electrode PE2 during a process of etching the electrodes RME, which will be described later, during a manufacturing process of the display device 10. The passivation layer PV may be disposed on the second pad electrode PE2 in the pad area PDA to form a second pad contact hole (e.g., a second pad contact opening) CTP2 exposing the second pad electrode PE2 in the third direction DR3 so that a third pad electrode PE3, to be described later, and the second pad electrode PE2 can be electrically connected by contacting each other.

In some embodiments, the passivation layer PV may include, but is not limited to, an inorganic insulating material, such as silicon oxide (SiOₓ), silicon nitride (SiNₓ), or silicon oxynitride (SiOₓN_{y}).

The via layer VIA may be disposed on the passivation layer PV. The via layer VIA may cover an upper surface of the passivation layer PV in the display area DPA. The via layer VIA may be disposed in the display area DPA but may not be disposed in at least the pad area PDA of the non-display area NDA. This may be because a via material layer disposed in the pad area PDA is removed during the manufacturing process of the display device 10.

The via layer VIA may include an organic insulating material, such as

polyimide (PI), and may provide a flat upper surface compensating for a step difference caused by conductive layers under the via layer VIA. However, in some embodiments, the via layer VIA may be omitted.

The display device 10 may include, as the display element layer disposed on the via layer VIA, the electrodes RME, the bank layer BNL, the light emitting elements ED, and the connection electrodes CNE. In addition, the display device 10 may include the insulating layers PAS1 and PAS2.

The electrodes RME (e.g., RME1 and RME2) may be disposed on the via layer VIA. For example, the electrodes RME may be directly disposed on the via layer VIA and may be spaced apart to face each other. The electrodes RME may include the first electrode RME1 and the second electrode RME2. The first electrode RME1 and the second electrode RME2 may overlap the bank portion BNP and the barrier portions BP1 and BP2 of the bank layer BNL, which will be described later. The first electrode RME1 may overlap the bank portion BNP and a first barrier portion BP1, and the second electrode RME2 may overlap the bank portion BNP and a second barrier portion BP2.

Each of the first electrode RME1 and the second electrode RME2 may be disposed in the emission area EMA and the sub-area SA. The electrodes RME of different subpixels SPXn adjacent to each other in the first direction DR1 may be spaced apart or separated from each other in the separation portion ROP disposed in the sub-area SA.

The first electrode RME1 and the second electrode RME2 may be spaced apart from each other, and a space between the first electrode RME1 and the second electrode RME2 may overlap the first opening OP1 in the bank layer BNL. In an embodiment, a distance between the first electrode RME1 and the second electrode RME2 spaced apart from each other may be smaller than a width of the first opening OP1 in the bank layer BNL or a distance between the first barrier portion BP1 and the second barrier portion BP2. The first opening OP1 may have a width sufficient to allow the light emitting elements ED to be disposed in the first opening OP1, and the first electrode RME1 and the second electrode RME2 may be spaced apart by a distance that allows both ends of the light emitting elements ED to be placed on the first electrode RME1 and the second electrode RME2.

Each of the electrodes RME may directly contact the second conductive layer 300 through an electrode contact hole (e.g., an electrode contact opening) CTD or CTS in a portion overlapping the bank layer BNL between the emission area EMA and the sub-area SA. A first electrode contact hole (e.g., a first electrode contact opening) CTD may be formed in an area in which the bank layer BNL and the first electrode RME1 overlap, and a second electrode contact hole (e.g., a second electrode contact opening) CTS may be formed in an area in which the bank layer BNL and the second electrode RME2 overlap. The first electrode RME1 may contact the source electrode SE through the first electrode contact hole CTD penetrating the via layer VIA and the passivation layer PV. The second electrode RME2 may contact the first conductive pattern CDP1 through the second electrode contact hole CTS penetrating the via layer VIA and the passivation layer PV. The first electrode RME1 may be electrically connected to the transistor through the source electrode SE to receive the first power supply voltage, and the second electrode RME2 may be electrically connected to the second voltage wiring VL2 through the first conductive pattern CDP1 to receive the second power supply voltage. However, the present disclosure is not limited thereto.

The electrodes RME may include a conductive material having high reflectivity. For example, each of the electrodes RME may include a metal, such as silver (Ag), copper (Cu) or aluminum (Al), may be an alloy including aluminum (Al), nickel (Ni) or lanthanum (La), or may have a structure in which a metal layer, such as titanium (Ti), molybdenum (Mo) or niobium (Nb), and the above alloy are stacked. In some embodiments, each of the electrodes RME may be a double layer or a multilayer structure in which an alloy including aluminum (Al) and at least one metal layer made of titanium (Ti), molybdenum (Mo) or niobium (Nb) are stacked.

However, the present disclosure is not limited thereto, and each electrode RME may further include a transparent conductive material. For example, each electrode RME may include a material such as ITO, IZO or ITZO. In some embodiments, each electrode RME may have a structure in which a transparent conductive material and a metal layer having high reflectivity are each stacked in one or more layers or may be formed as a single layer including them. For example, each electrode RME may have a stacked structure of ITO/Ag/ITO, ITO/Ag/IZO, or ITO/Ag/ITZO/IZO. The electrodes RME may be electrically connected to the light emitting elements ED and may reflect some of the light emitted from the light emitting elements ED in an upward direction above the substrate SUB.

The first insulating layer PAS1 may be disposed in the display area DPA and the pad area PDA of the non-display area NDA. The first insulating layer PAS1 may be disposed on the via layer VIA on which the electrodes RME are formed and may be disposed on the passivation layer PV in the pad area PDA. The first insulating layer PAS1 may overlap the barrier portions BP1 and BP2 and the bank portion BNP of the bank layer BNL, which will be described later.

As illustrated in FIG. 7, the first insulating layer PAS1 may be disposed in the entire subpixel SPXn except for a portion of the sub-area SA. For example, the first insulating layer PAS1 may be disposed in the entire subpixel SPXn except for the first contact portion CT1, the second contact portion CT2 and the separation portion ROP of the sub-area SA.

The first insulating layer PAS1 may be directly disposed on the via layer VIA, the first electrode RME1, and the second electrode RME2 in the display area DPA to cover them. The first insulating layer PAS1 may protect the first electrode RME1 while insulating the first electrode RME1 and the second electrode RME2 from each other. As will be described later, a developer for forming the bank layer BNL may be applied on the electrodes RME. However, because the first insulating layer PAS1 protects the electrodes RME, it may prevent the electrodes RME from being galvanically corroded by the developer. In addition, the first insulating layer PAS1 may prevent direct contact of the light emitting elements ED on the first insulating layer PAS1 with other members and, thus, may prevent damage to the light emitting elements ED.

In an embodiment, the first insulating layer PAS1 may have a thickness (e.g., a sufficient thickness or predetermined thickness) to protect the electrodes RME from the developer (see, e.g., FIG. 10). The first insulating layer PAS1 may have a thickness TT1 in a range of about 500 to about 3000 Å, such as a thickness TT1 in a range of about 1000 to about 2000 Å. The thickness TT1 of the first insulating layer PAS1 may be smaller than (or less than) a thickness TT2 of the second insulating layer PAS2, to be described later. For example, the thickness TT1 of the first insulating layer PAS1 may be in a range of about 30% to about 70% of the thickness TT2 of the second insulating layer PAS2. The thickness TT1 of the first insulating layer PAS1 may be smaller than the thickness TT2 of the second insulating layer PAS2, thereby preventing an increase in the total thickness of the insulating layers disposed on the display element layer.

The first insulating layer PAS1 may include the first contact portion CT1 and the second contact portion CT2 penetrating the first insulating layer PAS1 in the sub-area SA of the display area DPA and at least partially exposing the first electrode RME1 and the second electrode RME2. The first connection electrode CNE1, to be described later, and the first electrode RME1 may be electrically connected to each other through the first contact portion CT1 penetrating the first insulating layer PAS1, and the second connection electrode CNE2 and the second electrode RME2 may be electrically connected to each other through the second contact portion CT2 penetrating the first insulating layer PAS1.

The first insulating layer PAS1 may be disposed on the passivation layer PV in the pad area PDA. The first insulating layer PAS1 may be directly disposed on the upper surface of the passivation layer PV in the pad area PDA. The second pad contact hole CTP2, which exposes the second pad electrode PE2, may extend through the first insulating layer PAS1, the passivation layer PV, and the second insulating layer PAS2 in the pad area PDA. Side surfaces of the passivation layer PV, the first insulating layer PAS1, and the second insulating layer PAS2, which form the second pad contact hole CTP2 may be aligned with each other, but the present disclosure is not limited thereto.

The first insulating layer PAS1 may include silicon oxide or silicon nitride. In an embodiment, the first insulating layer PAS1 may be made of silicon oxide so that a gas outgassed from the via layer VIA can be released to the outside. However, the present disclosure is not limited thereto.

The bank layer BNL may be disposed on the first insulating layer PAS1. The bank layer BNL may include the bank portion BNP and the barrier portions BP1 and BP2 having a different height from the bank portion BNP. The bank layer BNL may be disposed in the entire subpixel SPXn except for a portion of the emission area EMA and a portion of the sub-area SA. The barrier portions BP1 and BP2 and the bank portion BNP may be integrated with each other and may be referred to as portions of the bank layer BNL according to their placement positions and heights.

Referring further to FIG. 8, the barrier portions BP1 and BP2 of the bank layer BNL may overlap the emission area EMA of each subpixel SPXn. The barrier portions BP1 and BP2 may extend in the first direction DR1 and may be spaced apart from each other with the first opening OP1 in the emission area EMA interposed between them. For example, the barrier portions BP1 and BP2 may include the first barrier portion BP1 and the second barrier portion BP2 spaced apart from each other in the second direction DR2 with the first opening OP1 therebetween. The first barrier portion BP1 may be disposed on the left side of the center of the emission area EMA, which is a first side in the second direction DR2, and the second barrier portion BP2 may be spaced apart from the first barrier portion BP1 and disposed on the right side of the center of the emission area EMA, which is a second side in the second direction DR2. The bank portion BNP may be disposed between the first barrier portion BP1 and the second barrier portion BP2 of different subpixels SPXn. A plurality of light emitting elements ED may be disposed in the first opening OP1 between the first barrier portion BP1 and the second barrier portion BP2.

The first barrier portion BP1 and the second barrier portion BP2 may extend in the first direction DR1 and may be integrated with a portion of the bank portion BNP of the bank layer BNL, which surrounds the emission area EMA. A length of each of the barrier portions BP1 and BP2 in the first direction DR1 may be the same as a length of the emission area EMA in the first direction DR1. The first barrier portion BP1 and the second barrier portion BP2 may have the same width in the second direction DR2. However, the present disclosure is not limited thereto, and the first barrier portion BP1 and the second barrier portion BP2 may also have different widths. For example, any one barrier portion may have a greater width than the other barrier portion. Although two barrier portions BP1 and BP2 having the same width are disposed in the subpixel SPXn in the drawings, the present disclosure is not limited thereto. The number and shape of the barrier portions BP1 and BP2 may vary according to the number or arrangement structure of the electrodes RME.

The barrier portions BP1 and BP2 may be disposed on the first insulating layer PAS1. For example, the barrier portions BP1 and BP2 may be directly disposed on the first insulating layer PAS1, and at least a portion of each of the barrier portions BP1 and BP2 may protrude from an upper surface of the first insulating layer PAS1. The protruding portion of each of the barrier portions BP1 and BP2 may have inclined side surfaces or curved side surfaces with a curvature (e.g., a predetermined curvature). For example, each of the barrier portions BP1 and BP2 may have a shape having an outer surface curved with a curvature in cross section and may have, for example, a semicircular or semielliptical shape.

The bank portion BNP of the bank layer BNL may be disposed on the first insulating layer PAS1. The bank portion BNP may include portions extending in the first direction DR1 and the second direction DR2 and may surround each subpixel SPXn. The bank portion BNP may surround the emission area EMA and the sub-area SA of each subpixel SPXn to separate them and may be integrated with the barrier portions BP1 and BP2 disposed in the emission area EMA. The bank portion BNP of the bank layer BNL may surround the outermost periphery of the display area DPA to separate the display area DPA and the non-display area NDA. The bank portion BNP may not overlap the emission area EMA and the sub-area SA. The bank layer BNL may be disposed in the entire display area DPA and may be formed in a grid shape. Areas exposed by the bank layer BNL in the display area DPA may be the first opening OP1 disposed in the emission area EMA and the second opening OP2 disposed in the sub-area SA. From among the bank layer BNL, a portion in which the barrier portions BP1 and BP2 are disposed may be the emission area EMA.

The bank portion BNP of the bank layer BNL may have a greater thickness than the barrier portions BP1 and BP2. An upper surface of the bank portion BNP may be at a greater height than those of the barrier portions BP1 and BP2. The bank portion BNP may prevent ink from overflowing to adjacent subpixels SPXn during an inkjet printing process during the manufacturing process of the display device 10. The bank layer BNL may include, but is not limited to, an organic insulating material, such as polyimide (PI).

The second insulating layer PAS2 may be disposed in the display area DPA and the pad area PDA of the non-display area NDA. The second insulating layer PAS2 may be disposed on the bank layer BNL and the first insulating layer PAS1 in the display area DPA and may be disposed on the first insulating layer PAS1 in the pad area PDA.

As illustrated in FIG. 9, the second insulating layer PAS2 may be disposed in the emission area EMA and the sub-area SA of the subpixel SPXn. For example, the second insulating layer PAS2 may be disposed in the entire emission area EMA and may be disposed in the sub-area SA except for the first contact portion CT1, the second contact portion CT2, and the separation portion ROP. For example, the second insulating layer PAS2 may not overlap and may not be disposed in areas other than the emission area EMA and the sub-area SA.

The second insulating layer PAS2 may cover the first insulating layer PAS1 exposed by the first opening OP1 in the bank layer BNL in the emission area EMA. In the emission area EMA, the second insulating layer PAS2 may be directly disposed on the barrier portions BP1 and BP2 of the bank layer BNL and may overlap the barrier portions BP1 and BP2 and cover the barrier portions BP1 and BP2. The second insulating layer PAS2 may not be disposed on the bank portion BNP of the bank layer BNL and may not overlap the bank portion BNP.

In an embodiment, the emission area EMA defined by the bank portion BNP of the bank layer BNL may be coated with ink, in which the light emitting elements ED are dispersed, during a process of aligning the light emitting elements ED. The surface of the bank portion BNP may be hydrophobic so that the ink does not overflow to adjacent subpixels SPXn. Because the second insulating layer PAS2 does not cover the bank portion BNP, the bank portion BNP can prevent the ink from overflowing when the ink is applied.

In an embodiment, the second insulating layer PAS2 may have a thickness TT2 in a range of about 1000 to about 3000 Å. The thickness TT2 of the second insulating layer PAS2 may be greater than the thickness TT1 of the first insulating layer PAS1. The sum (TT1+TT2) of the respective thicknesses of the first insulating layer PAS1 and the second insulating layer PAS2 may be in a range of about 1000 to about 5000 Å. In one embodiment, the sum (TT1+TT2) of the respective thicknesses of the first insulating layer PAS1 and the second insulating layer PAS2 may be in a range of about 1000 to about 3000 Å. When the first insulating layer PAS1 and the second insulating layer PAS2 have a thickness within the above-described range, an increase in the total thickness of the insulating layers disposed on the display element layer may be prevented.

The second insulating layer PAS2 may be disposed under the light emitting elements ED. In an area overlapping the light emitting elements ED, the second insulating layer PAS2 may directly contact the first insulating layer PAS1. Here, the area overlapping the light emitting elements ED may be disposed in the first opening OP1 in the bank layer BNL. In an embodiment, a lower surface of the second insulating layer PAS2 may directly contact the upper surface of the first insulating layer PAS1.

Together with the first insulating layer PAS1, the second insulating layer PAS2 may form the first contact portion CT1 and the second contact portion CT2, which at least partially expose the first electrode RME1 and the second electrode RME2 in the sub-area SA. The second insulating layer PAS2 may be disposed on the first insulating layer PAS1 in the pad area PDA. The second insulating layer PAS2 may be directly disposed on the first insulating layer PAS1 in the pad area PDA. The second pad contact hole CTP2, which exposes the second pad electrode PE2, may extend through the second insulating layer PAS2 and the first insulating layer PAS1 in the pad area PDA.

The second insulating layer PAS2 may include the same material as the first insulating layer PAS1. The second insulating layer PAS2 may include silicon oxide or silicon nitride. In an embodiment, the second insulating layer PAS2 may be made of silicon oxide so that a gas outgassed from the via layer VIA can be released to the outside. However, the present disclosure is not limited thereto.

The light emitting elements ED may be disposed in the emission area EMA. The light emitting elements ED may not be disposed in the sub-area SA. Because the bank layer BNL is formed to separate the emission area EMA and the sub-area SA of each subpixel SPXn as described above, ink in which the light emitting elements ED are dispersed may be sprayed only into the emission area EMA. Accordingly, the light emitting elements ED may be disposed in the emission area EMA but may not be disposed in the sub-area SA.

The light emitting elements ED may be disposed between the first barrier portion BP1 and the second barrier portion BP2 of the bank layer BNL in the emission area EMA. In some embodiments, each of the light emitting elements ED may extend in a direction, and the direction in which each of the light emitting elements ED extends may be substantially perpendicular to the direction in which the first electrode RME1 and the second electrode RME2 extend. However, the present disclosure is not limited thereto, and the direction in which the light emitting elements ED extend may also be oblique to the direction in which the first electrode RME1 and the second electrode RME2 extend. In an area in which the first barrier portion BP1 and the second barrier portion BP2 are spaced apart to face each other, the light emitting elements ED may be aligned such that at least one of both ends lies on the first electrode RME1 or the second electrode RME2.

The light emitting elements ED may be disposed in the first opening OP1 in the bank layer BNL and may be spaced apart from each other. The light emitting elements ED may be spaced apart from each other in the first direction DR1 between the first barrier portion BP1 and the second barrier portion BP2. The light emitting elements ED may be arranged in a line between the first barrier portion BP1 and the second barrier portion BP2, and the light emitting elements ED adjacent to each other in the first direction DR1 may be separated by a random distance.

The light emitting elements ED disposed in the subpixels SPXn may emit light of different wavelength bands depending on materials that form semiconductor layers, to be described later. However, the present disclosure is not limited thereto, and the light emitting elements ED disposed in the subpixels SPXn may also emit light of the same color by including the semiconductor layers made of the same material. The light emitting elements ED may be electrically connected to the electrodes RME and the conductive layers under the via layer VIA by contacting the connection electrodes CNE (e.g., CNE1 and CNE2) and may emit light of a specific wavelength band in response to electrical signals.

The connection electrodes CNE may be disposed across the emission area EMA and the sub-area SA in the display area DPA. The connection electrodes CNE may include the first connection electrode CNE1 and the second connection electrode CNE2. The first connection electrode CNE1 and the second connection electrode CNE2 may each extend in the first direction DR1 and may be spaced apart from each other in the second direction DR2.

The first connection electrode CNE1 may overlap the first electrode RME1 in the third direction DR3 in the emission area EMA and the sub-area SA of each pixel PX. The first connection electrode CNE1 may overlap an end of each light emitting element ED in the emission area EMA. The first connection electrode CNE1 may contact the first electrode RME1 through the first contact portion CT1 in the sub-area SA and may contact the end of each light emitting element ED in the emission area EMA. Because the first connection electrode CNE1 contacts the end of each light emitting element ED and the first electrode RME1, the end of each light emitting element ED and the first electrode RME1 may be electrically connected through the first connection electrode CNE1.

The second connection electrode CNE2 may overlap the second electrode RME2 in the third direction DR3 in the emission area EMA and the sub-area SA of each pixel PX. The second connection electrode CNE2 may overlap the other end of each light emitting element ED in the emission area EMA. The second connection electrode CNE2 may contact the second electrode RME2 through the second contact portion CT2 in the sub-area SA and may contact the other end of each light emitting element ED in the emission area EMA. Because the second connection electrode CNE2 contacts the other end of each light emitting element ED and the second electrode RME2, the other end of each light emitting element ED and the second electrode RME2 may be electrically connected through the second connection electrode CNE2.

Although the first connection electrode CNE1 and the second connection electrode CNE2 respectively contact the first electrode RME1 and the second electrode RME2 in the sub-area SA in the drawings, the present disclosure is limited thereto. For example, the first connection electrode CNE1 and the second connection electrode CNE2 may also respectively contact the first electrode RME1 and the second electrode RME2 in the emission area EMA.

The third pad electrode PE3 may be disposed in the pad area PDA of the non-display area NDA. The third pad electrode PE3 may be disposed on the second insulating layer PAS2 in the pad area PDA. The third pad electrode PE3 may overlap the first pad electrode PE1 and the second pad electrode PE2 in the third direction DR3 in the pad area PDA.

The third pad electrode PE3 may be electrically connected to the second pad electrode PE2 by contacting the second pad electrode PE2 through the second pad contact hole CTP2 formed in the passivation layer PV, the first insulating layer PAS1, and the second insulating layer PAS2.

The first connection electrode CNE1, the second connection electrode CNE2, and the third pad electrode PE3 may include the same material and may be disposed on the same layer. The first connection electrode CNE1, the second connection electrode CNE2, and the third pad electrode PE3 may be formed by the same process. For example, the first connection electrode CNE1, the second connection electrode CNE2, and the third pad electrode PE3 may be concurrently (or simultaneously) formed through a single mask process. The first connection electrode CNE1, the second connection electrode CNE2, and the third pad electrode PE3 may include a conductive material. For example, the first connection electrode CNE1, the second connection electrode CNE2, and the third pad electrode PE3 may include ITO, IZO, ITZO, aluminum (Al), or the like.

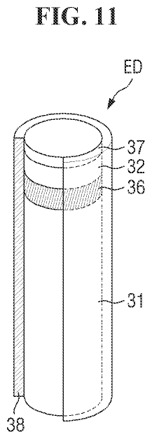

FIG. 11 is a schematic view of a light emitting element ED according to an embodiment.

Referring to FIG. 11, the light emitting element ED may be a light emitting diode. For example, the light emitting element ED may be an inorganic light emitting diode having a size in a nanometer or micrometer range and made of an inorganic material. When an electric field is formed in a specific direction between two electrodes facing each other, the light emitting element ED may be aligned between the two electrodes between which polarity is formed.

The light emitting element ED, according to an embodiment, may extend in one direction. The light emitting element ED may be shaped like a cylinder, a rod, a wire, a tube, or the like. However, the shape of the light emitting element ED is not limited thereto, and the light emitting element ED may have various shapes including polygonal prisms, such as a cube, a rectangular parallelepiped, or a hexagonal prism, and a shape extending in a direction and having a partially inclined outer surface.

The light emitting element ED may include a semiconductor layer doped with a dopant of any conductivity type (e.g., a p-type or an n-type). The semiconductor layer may receive an electrical signal from an external power source and emit light of a specific wavelength band. The light emitting element ED may include a first semiconductor layer 31, a second semiconductor layer 32, a light emitting layer 36, an electrode layer 37, and an insulating film 38.

The first semiconductor layer 31 may be an n-type semiconductor. The first semiconductor layer 31 may include a semiconductor material having a chemical formula of AlₓGa_{y}In_{1-x-y}N (0≤x≤1, 0≤y≤1, 0≤x+y≤1). For example, the first semiconductor layer 31 may be any one or more of AlGaInN, GaN, AlGaN, InGaN, AlN, and InN doped with an n-type dopant. The n-type dopant used to dope the first semiconductor layer 31 may be Si, Ge, Sn, or the like.

The second semiconductor layer 32 is disposed on the first semiconductor layer 31 with the light emitting layer 36 interposed between them. The second semiconductor layer 32 may be a p-type semiconductor. The second semiconductor layer 32 may include a semiconductor material having a chemical formula of AlₓGa_{y}In_{1-x-y}N (0≤x≤1, 0≤y≤1, 0≤x+y≤1). For example, the second semiconductor layer 32 may be any one or more of AlGaInN, GaN, AlGaN, InGaN, AlN, and InN doped with a p-type dopant. The p-type dopant used to dope the second semiconductor layer 32 may be Mg, Zn, Ca, Ba, or the like.

Although each of the first semiconductor layer 31 and the second semiconductor layer 32 is illustrated as being one layer in the drawing, the present disclosure is not limited thereto. Each of the first semiconductor layer 31 and the second semiconductor layer 32 may include more layers; for example, they may further include a clad layer or a tensile strain barrier reducing (TSBR) layer depending on the material of the light emitting layer 36. For example, the light emitting element ED may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may be any one or more of AlGaInN, GaN, AlGaN, InGaN, AlN, InN, and SLs doped with an n-type dopant. The semiconductor layer disposed between the second semiconductor layer 32 and the light emitting layer 36 may be any one or more of AlGaInN, GaN, AlGaN, InGaN, AlN, and InN doped with a p-type dopant.

The light emitting layer 36 is disposed between the first semiconductor layer 31 and the second semiconductor layer 32. The light emitting layer 36 may include a material having a single or multiple quantum well structure. When the light emitting layer 36 includes a material having a multiple quantum well structure, it may have a structure in which a plurality of quantum layers and a plurality of well layers are alternately stacked. The light emitting layer 36 may emit light through combination of electron-hole pairs according to electrical signals received through the first semiconductor layer 31 and the second semiconductor layer 32. The light emitting layer 36 may include a material such as AlGaN, AlGaInN, or InGaN. For example, when the light emitting layer 36 has a multiple quantum well structure in which a quantum layer and a well layer are alternately stacked, the quantum layer may include a material such as AlGaN or AlGaInN, and the well layer may include a material such as GaN or AlInN.

The light emitting layer 36 may also have a structure in which a semiconductor material having a large band gap energy and a semiconductor material having a small band gap energy are alternately stacked or may include different group 3 to 5 semiconductor materials depending on the wavelength band of light that it is configured to emit. Light emitted from the light emitting layer 36 is not limited to light in a blue wavelength band. In some embodiments, the light emitting layer 36 may emit light in a red or green wavelength band.

The electrode layer 37 may be an ohmic connection electrode. However, the present disclosure is not limited thereto, and the electrode layer 37 may also be a Schottky connection electrode. The light emitting element ED may include at least one electrode layer 37. The light emitting element ED may include one or more electrode layers 37, but the present disclosure is not limited thereto, and the electrode layer 37 may be omitted in some embodiments.

When the light emitting element ED is electrically connected to electrodes or connection electrodes in the display device 10, the electrode layer 37 may reduce the resistance between the light emitting element ED and the electrodes or the connection electrodes. The electrode layer 37 may include a conductive metal. For example, the electrode layer 37 may include at least any one of aluminum (Al), titanium (Ti), indium (In), gold (Au), silver (Ag), indium tin oxide (ITO), indium zinc oxide (IZO), and indium tin zinc oxide (ITZO).

The insulating film 38 surrounds outer surfaces of the semiconductor layers and the electrode layer described above. For example, the insulating film 38 may surround an outer surface of at least the light emitting layer 36 but may expose both ends (e.g., opposite ends) of the light emitting element ED in a longitudinal direction. In addition, an upper surface of the insulating film 38 may be rounded in cross section in an area adjacent to at least one end of the light emitting element ED.

The insulating film 38 may include an insulating material, for example, at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). Although the insulating film 38 is illustrated as a single layer in the drawing, the present disclosure is not limited thereto. In some embodiments, the insulating film 38 may be formed in a multilayer structure in which a plurality of layers are stacked.

The insulating film 38 may protect the semiconductor layers and the electrode layer of the light emitting element ED. The insulating film 38 may prevent an electrical short circuit that may occur when the light emitting layer 36 directly contacts an electrode that transmits an electrical signal to the light emitting element ED. In addition, the insulating film 38 may prevent a reduction in luminous efficiency of the light emitting element ED.

In addition, an outer surface of the insulating film 38 may be treated. The light emitting element ED may be sprayed onto electrodes in a state in which it is dispersed in an ink and then aligned. Here, the surface of the insulating film 38 may be hydrophobic or hydrophilic-treated so that the light emitting elements ED disperse in the ink without being agglomerated with other adjacent light emitting elements ED.

A method of manufacturing the display device 10 described above according to an embodiment of the present disclosure will now be described with reference to other drawings.

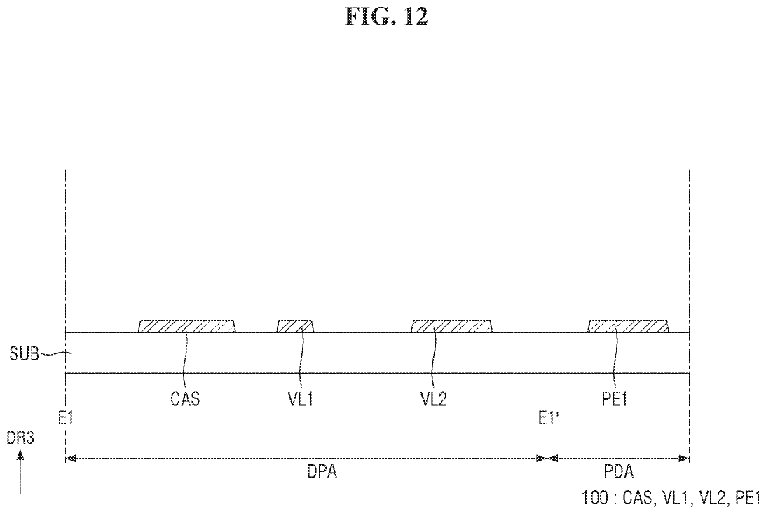

FIGS. 12 through 22 are cross-sectional views sequentially illustrating steps of a process of manufacturing a display device 10 according to an embodiment. The process of manufacturing the display device 10 illustrated in FIGS. 12 through 22 may correspond to the display device 10 shown in FIG. 4 and described above.

Referring to FIGS. 12 through 22, a method of manufacturing a display device 10 according to an embodiment may include forming a first conductive layer 100, forming a buffer layer BL, forming a semiconductor layer 200, forming a gate insulating layer GI and a second conductive layer 300, forming a passivation layer PV, forming a via layer VIA, forming electrodes RME, forming a first insulating layer PAS1, forming a bank layer BNL, forming a second insulating layer PAS2, aligning light emitting elements ED, and forming connection electrodes CNE. The above operations will now be sequentially described.

First, referring to FIG. 12, a substrate SUB is prepared, and the first conductive layer 100 is formed on the substrate SUB. The first conductive layer 100 may be formed by depositing a conductive material and performing a patterning process using a mask. For example, a first conductive material layer may be deposited on the entire surface of the substrate SUB and may then be patterned through a photolithography process to form the first conductive layer 100 as illustrated in FIG. 12. The first conductive layer 100 may include a first voltage wiring VL1, a second voltage wiring VL2, and a bottom metal layer CAS disposed in a display area DPA and may include a first pad electrode PE1 disposed in a pad area PDA.

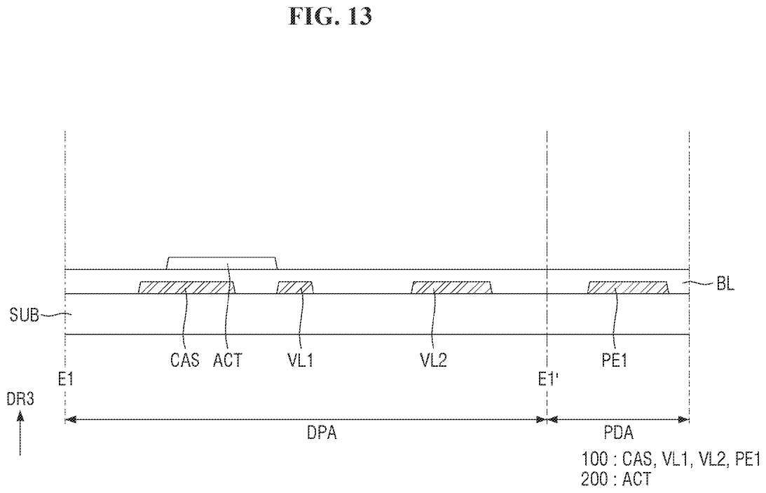

Next, referring to FIG. 13, the buffer layer BL is formed on the entire surface of the substrate SUB on which the first conductive layer 100 is formed, and the semiconductor layer 200 is formed on the buffer layer BL. The buffer layer BL may completely cover the first conductive layer 100. For example, the buffer layer BL may completely cover the first voltage wiring VL1, the second voltage wiring VL2, and the bottom metal layer CAS disposed in the display area DPA and the first pad electrode PE1 disposed in the pad area PDA. The semiconductor layer 200 may be formed by a mask process. For example, a semiconductor material may be deposited on the entire surface of the buffer layer BL and may then be patterned through a photolithography process to form the semiconductor layer 200 as illustrated in FIG. 13. The semiconductor layer 200 may include an active layer ACT of a transistor.

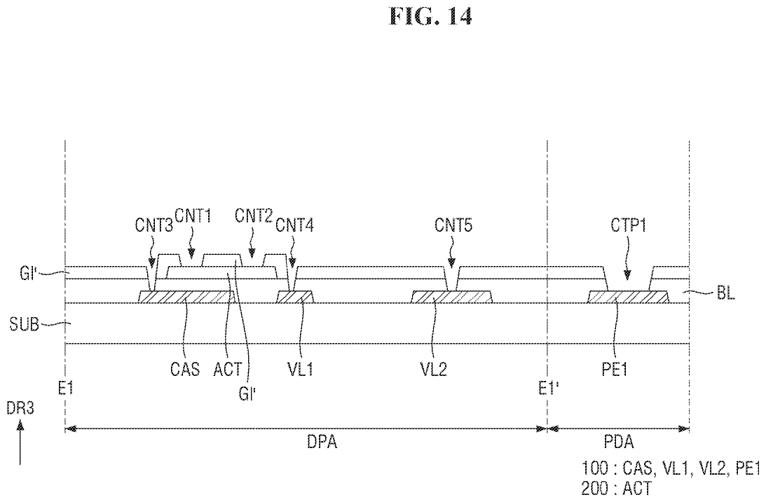

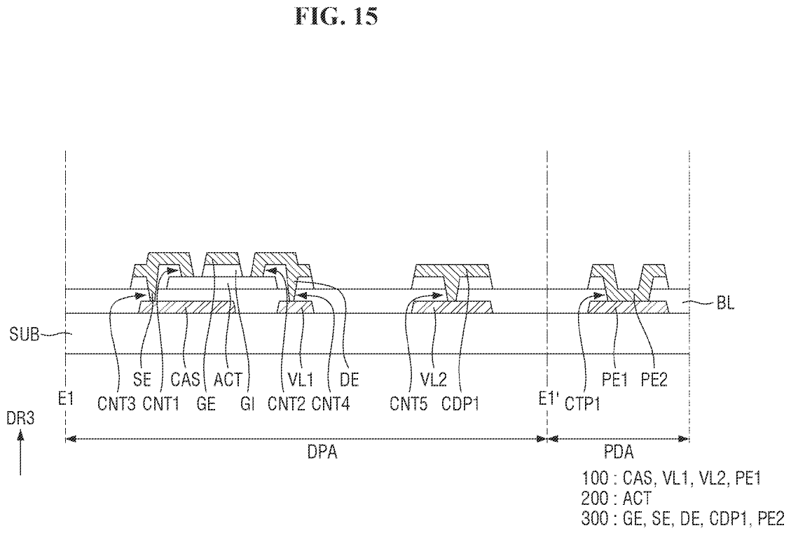

Next, referring to FIGS. 14 and 15, the gate insulating layer GI and the second conductive layer 300 are formed on the buffer layer BL on which the semiconductor layer 200 is formed.

For example, a gate insulating material layer GI′ completely covering the semiconductor layer 200 is formed on the buffer layer BL on which the semiconductor layer 200 is formed. Then, a first contact hole CNT1 and a second contact hole CNT2 exposing portions of the semiconductor layer 200, a third contact hole CNT3 exposing a portion of the bottom metal layer CAS, which is the first conductive layer 100, and a fourth contact hole CNT4 and a fifth contact hole CNT5 respectively exposing the first voltage wiring VL1 and the second voltage wiring VL2 are formed. In addition, a first pad contact hole CTP1 exposing a portion of the first pad electrode PE1 which is the first conductive layer 100 is formed. The first contact hole CNT1 and the second contact hole CNT2 exposing portions of the semiconductor layer 200 may penetrate the gate insulating material layer GI′, and the third contact hole CNT3, the fourth contact hole CNT4, the fifth contact hole CNT5 and the first pad contact hole CTP1 exposing portions of the first conductive layer 100 may penetrate the gate insulating material layer GI′ and the buffer layer BL. The first contact hole CNT1, the second contact hole CNT2, the third contact hole CNT3, the fourth contact hole CNT4, the fifth contact hole CNT5, and the first pad contact hole CTP1 may be formed by a single mask process.

Next, as illustrated in FIG. 15, the patterned gate insulating layer GI and the second conductive layer 300 are formed on the buffer layer BL. The patterned gate insulating layer GI and the second conductive layer 300 may be formed by a single mask process. For example, a second conductive material layer is deposited on the entire surface of the gate insulating material layer GI′. Then, a photoresist layer is applied on the second conductive material layer, and a photoresist pattern is formed through exposure and development. Next, the second conductive material layer and the gate insulating material layer GI′ are all etched at once (e.g., are concurrently or simultaneously etched) using the photoresist pattern as an etch mask to form the gate insulating layer GI and the second conductive layer 300. Because the second conductive material layer and the gate insulating material layer GI′ are all etched at once, lateral sides of the second conductive layer 300 and lateral sides of the gate insulating layer GI may be aligned with each other. Subsequently, a separate process of removing the photoresist pattern may be performed. The second conductive layer 300 may include a gate electrode GE, a drain electrode DE, a source electrode SE, a first conductive pattern CDP1, and a second pad electrode PE2.

The source electrode SE electrically connects the active layer ACT and the bottom metal layer CAS through the first contact hole CNT1 and the third contact hole CNT3. The drain electrode DE electrically connects the active layer ACT and the first voltage wiring VL1 through the second contact hole CNT2 and the fourth contact hole CNT4. The first conductive pattern CDP1 is electrically connected to the second voltage wiring VL2 through the fifth contact hole CNT5. The second pad electrode PE2 is electrically connected to the first pad electrode PE1 through the first pad contact hole CTP1.

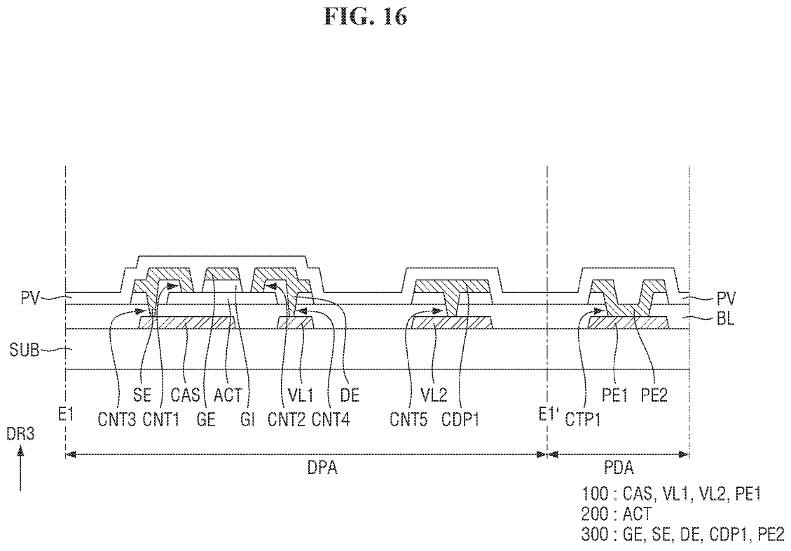

Next, referring to FIG. 16, the passivation layer PV is formed on the substrate SUB on which the second conductive layer 300 and the buffer layer BL are formed. The passivation layer PV may be disposed over the whole of the display area DPA and a non-display area NDA and may completely cover the second conductive layer 300. In addition, the passivation layer PV may directly contact portions of the active layer ACT exposed by the first contact hole CNT1 and the second contact hole CNT2.

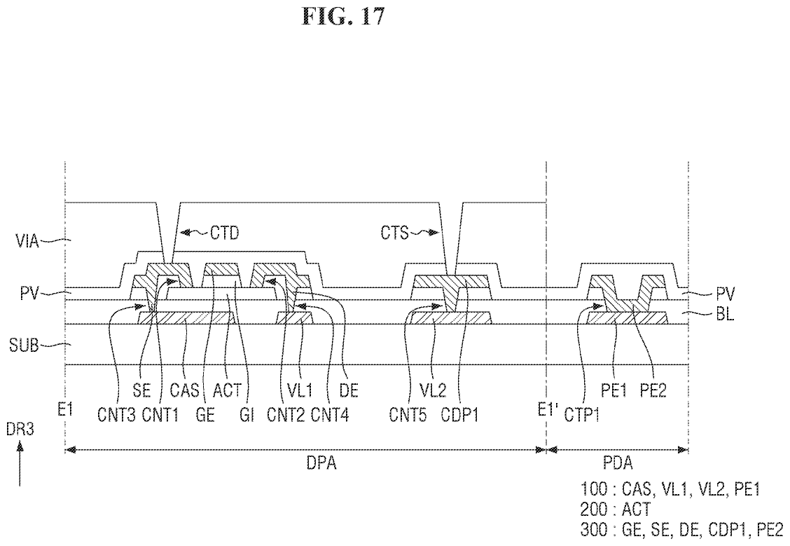

Next, referring to FIG. 17, the via layer VIA is formed on the substrate SUB on which the passivation layer PV is formed. The via layer VIA may be disposed in the display area DPA but may not be disposed in the pad area PDA. The via layer VIA may be etched by a mask process to form a first electrode contact hole CTD overlapping the source electrode SE and a second electrode contact hole CTS overlapping the first conductive pattern CDP1 in the display area DPA. In addition, the via layer VIA may be etched by the above-described mask process to expose the passivation layer PV formed in the pad area PDA of the non-display area NDA.

Next, the passivation layer PV exposed by the first electrode contact hole CTD and the second electrode contact hole CTS is etched using the patterned via layer VIA as a mask. Accordingly, the via layer VIA and the passivation layer PV may form the first electrode contact hole CTD and the second electrode contact hole CTS to expose the source electrode SE and the first conductive pattern CDP1. Therefore, a separate mask process may be unnecessary (or may be omitted) in the process of etching the passivation layer PV to form the first electrode contact hole CTD and the second electrode contact hole CTS.

The passivation layer PV disposed on the second pad electrode PE2 may be exposed when the via layer VIA is removed from the pad area PDA. When the via layer VIA is removed from the pad area PDA, the second pad electrode PE2 may be covered by the passivation layer PV and, thus, may not be exposed to the outside. Accordingly, an etchant used to etch the electrodes RME, which will be described later, may not (e.g,. may be unable to) penetrate into the second pad electrode PE2. This may prevent the second pad electrode PE2 from being etched.

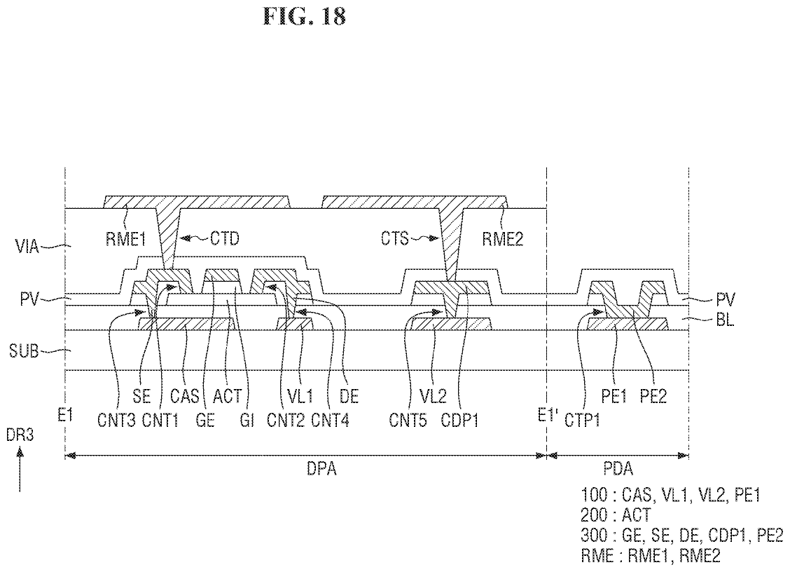

Next, referring to FIG. 18, the electrodes RME are formed on the via layer VIA. The electrodes RME may be formed by a mask process.

For example, in a process of forming the electrodes RME, an electrode material layer may be deposited in the whole of the display area DPA and the pad area PDA and may then be patterned through a photolithography process to form the patterned electrodes RME as illustrated in FIG. 18. In some embodiments, the patterning of the electrodes RME may be performed by wet etching using an etchant. In such an embodiment, the passivation layer PV disposed on the second pad electrode PE2 in the pad area PDA may prevent the etchant from penetrating into the second pad electrode PE2, thereby preventing the second pad electrode PE2 from being etched.

The electrodes RME may include a first electrode RME1 and a second electrode RME2. In the display area DPA, the first electrode RME1 may be deposited up to the inside of the first electrode contact hole CTD and may be electrically connected to the source electrode SE by contacting the source electrode SE, and the second electrode RME2 may be deposited up to the inside of the electrode contact hole CTS and may be electrically connected to the first conductive pattern CDP1 by contacting the first conductive pattern CDP1.

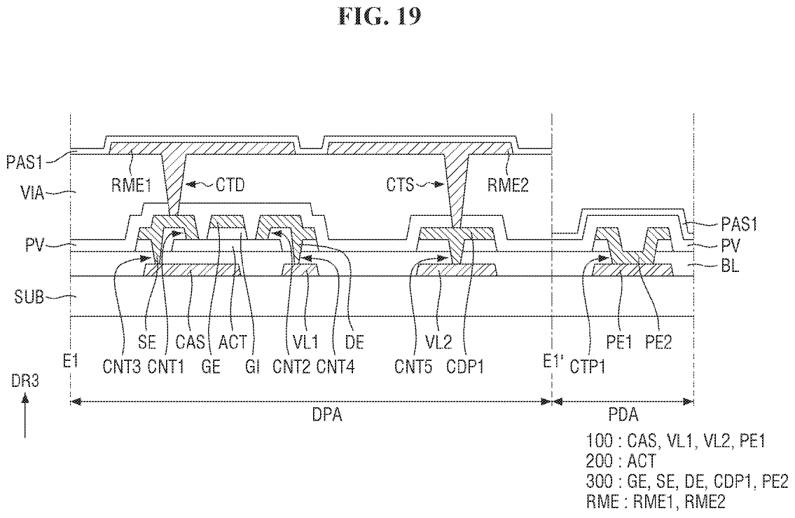

Next, referring to FIG. 19, the first insulating layer PAS1 is formed on the substrate SUB on which the electrodes RME are formed. Because the first insulating layer PAS1 is formed in the whole of the display area DPA and the non-display area NDA, it may be formed in the pad area PDA as well as in the display area DPA. Accordingly, the first insulating layer PAS1 may be disposed on the passivation layer PV disposed on the second pad electrode PE2 of the pad area PDA. As will be described later, the first insulating layer PAS1 may be formed to have a thickness in a range of about 1000 to about 3000 Å to protect the electrodes RME from a developer of the bank layer BNL while allowing a gas outgassed from the via layer VIA to be released to the outside. For example, the first insulating layer PAS1 may be formed to have a thickness of about 1000 Å. In addition, the first insulating layer PAS1 may be made of, for example, silicon oxide so that the gas can be released.

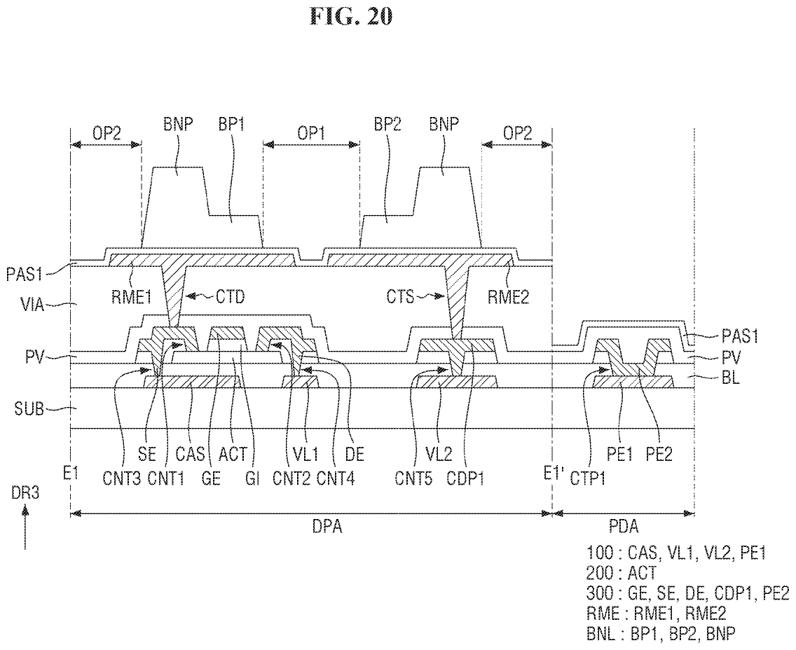

Next, referring to FIG. 20, the bank layer BNL is formed on the substrate SUB on which the first insulating layer PAS1 is formed. The bank layer BNL is disposed in the display area DPA and is not disposed in the non-display area NDA. The bank layer BNL is formed into barrier portions BP1 and BP2 and a bank portion BNP by a single mask process.

For example, a bank material layer is applied on the substrate SUB on which the first insulating layer PAS1 is formed, and a halftone mask including a transmissive area through which light is completely transmitted, a blocking area in which light is blocked, and a transflective area in which the amount of light transmitted is controlled is aligned over the substrate SUB. Next, light is irradiated toward the bank material layer from above the halftone mask, and then the bank material layer is developed using a developer to form the bank layer BNL. A portion of the bank material layer that corresponds to (e.g., is aligned with) the transmissive area is completely removed, and a portion of the bank material layer that corresponds to the blocking area remains as it forms the bank portion BNP. A portion of the bank material layer that corresponds to the transflective area forms the barrier portions BP1 and BP2 having a height lower than that of the bank portion BNP. In addition, the completely removed portion of the bank material layer forms a first opening OP1 and a second opening OP2.

In the process of developing the bank material layer, a developer, such as tetramethylammonium hydroxide (TMAH), may be used. When the electrodes RME are exposed to this developer, galvanic corrosion may occur, causing lifting or breaking. In an embodiment, the first insulating layer PAS1 completely covering the electrodes RME is formed, and the bank layer BNL is formed on the first insulating layer PAS1. Therefore, the developer is prevented from reaching the electrodes RME, thereby preventing lifting or breaking of the electrodes RME.

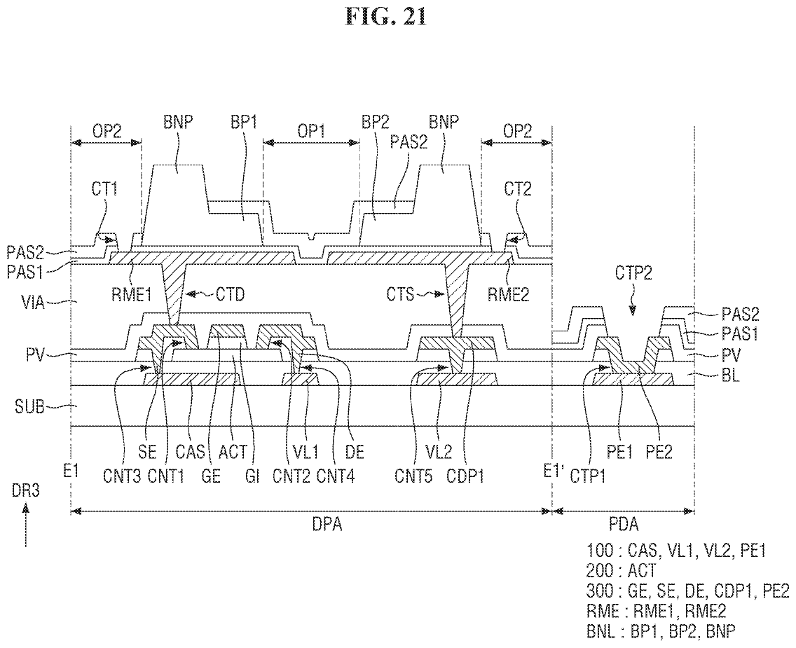

Next, referring to FIG. 21, the second insulating layer PAS2 is formed on the substrate SUB on which the bank layer BNL is formed. The second insulating layer PAS2 may be formed by a mask process. For example, a second insulating material layer may be deposited on the entire surface of the first insulating layer PAS1 on which the bank layer BNL is formed and may then be etched through a photolithography process to form the patterned second insulating layer PAS2 as illustrated in FIG. 21.

The patterned second insulating layer PAS2 may not overlap the bank portion BNP of the bank layer BNL in the display area DPA and may overlap the barrier portions BP1 and BP2 of the bank layer BNL. In addition, the second insulating layer PAS2 may be directly disposed on the first insulating layer PAS1 exposed by the first opening OP1 between the barrier portions BP1 and BP2 and may be directly disposed on the first insulating layer PAS1 exposed by the second opening OP2.

In the above mask process, the second insulating layer PAS2 and the first insulating layer PAS1 may be concurrently (or simultaneously) etched to form a first contact portion CT1 and a second contact portion CT2 penetrating the second insulating layer PAS2 and the first insulating layer PAS1 and to form a second pad contact hole CTP2 penetrating the first insulating layer PAS1, the second insulating layer PAS2, and the passivation layer PV in the pad area PDA. Accordingly, the first electrode RME1 is exposed by the first contact portion CT1, the second electrode RME2 is exposed by the second contact portion CT2, and the second pad electrode PE2 is exposed by the second pad contact hole CTP2.

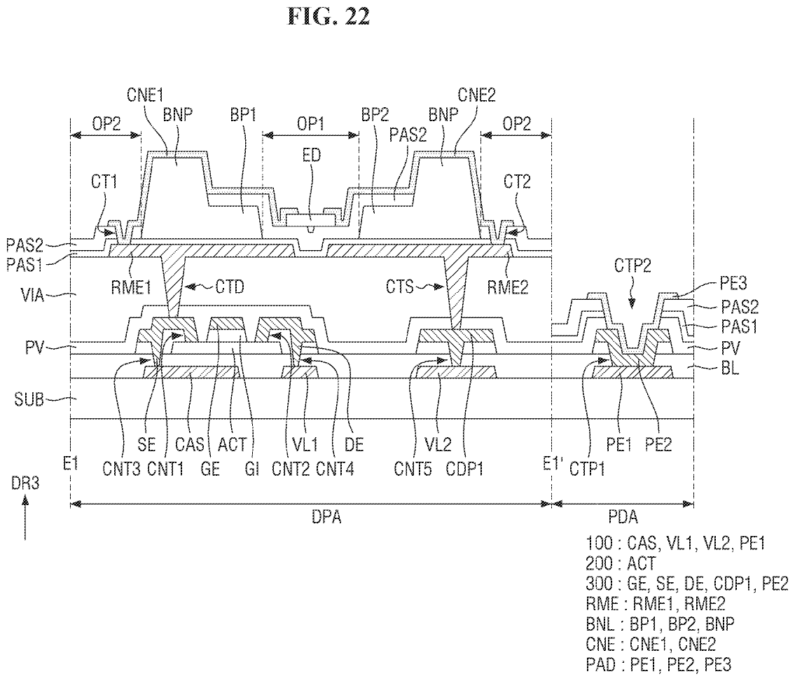

Next, referring to FIG. 22, a plurality of light emitting elements ED are aligned in the first opening OP1 formed between a first barrier portion BP1 and a second barrier portion BP2. Through an inkjet printing process, the light emitting elements ED may be placed (e.g., deposited) on the second insulating layer PAS2 located in the first opening OP1 between the first barrier portion BP1 and the second barrier portion BP2.

For example, an ink in which the light emitting elements ED are dispersed may be sprayed into an emission area EMA (see, e.g., FIG. 5) defined by the bank layer BNL. Then, alignment signals may be transmitted to the first electrode RME1 and the second electrode RME2. The alignment signals may change the position and orientation direction of the light emitting elements ED in the ink, thereby settling (or aligning) the light emitting elements ED on the second insulating layer PAS2 between the first electrode RME1 and the second electrode RME2.

Next, a connection electrode material layer is stacked on the second insulating layer PAS2 on which the light emitting elements ED and the bank layer BNL are formed and is then patterned through a photolithography process to form a first connection electrode CNE1 and a second connection electrode CNE2 in the display area DPA and a third pad electrode PE3 in the pad area PDA. The first connection electrode CNE1 is electrically connected to the first electrode RME1 through the first contact portion CT1, and the second connection electrode CNE2 is electrically connected to the second electrode RME1 through the second contact portion CT2. The third pad electrode PE3 is electrically connected to the second pad electrode PE2 through the second pad contact hole CTP2. Accordingly, the display device 10 according to the embodiment shown in FIG. 5 may be manufactured.

As described above, in the method of manufacturing the display device 10 according to an embodiment, the first insulating layer PAS1 completely covering the electrodes RME is formed and the bank layer BNL is formed on the first insulating layer PAS1. Therefore, a developer is prevented from reaching the electrodes RME, thereby preventing lifting or breaking of the electrodes RME.

Hereinafter, another embodiment of the display device 10 will be described. In the following embodiment, the same elements as those of the previously described embodiment are referred to by the same reference numerals. Any overlapping description will be omitted or given briefly, and differences therebetween will be primarily described.

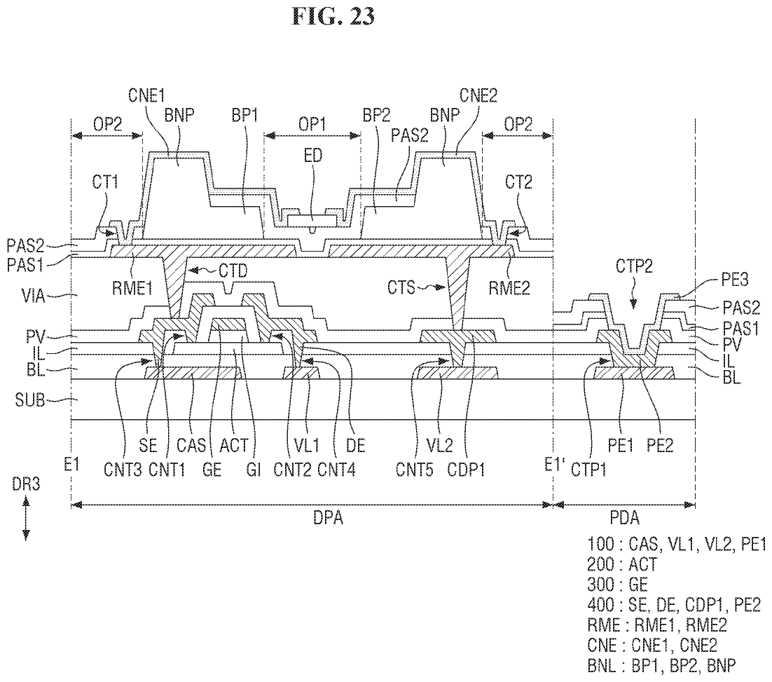

FIG. 23 is a cross-sectional view of a subpixel and a pad portion of a display device according to an embodiment.

The embodiment shown in FIG. 23 is different from the above-described embodiment shown in FIG. 5 in that a second conductive layer includes a gate electrode, and a third conductive layer including a source electrode, a drain electrode, a first conductive pattern, and a second pad electrode is formed.

A first conductive layer 100 including a bottom metal layer CAS, a first voltage wiring VL1, a second voltage wiring VL2, and a first pad electrode PE1 is disposed on a substrate SUB. A buffer layer BL is disposed on the first conductive layer 100, and a semiconductor layer 200 including an active layer ACT is disposed on the buffer layer BL. A gate insulating layer GI is disposed on the semiconductor layer 200, and a second conductive layer 300 is disposed on the gate insulating layer GI. The second conductive layer 300 may include a gate electrode GE. Respective side surfaces of the gate electrode GE and the gate insulating layer GI may be aligned with each other.

An interlayer insulating layer IL covering the second conductive layer 300 is disposed on the second conductive layer 300. The interlayer insulating layer IL may be disposed in a display area DPA and a pad area PDA. The interlayer insulating layer IL may be formed as a multilayer structure in which inorganic layers including at least any one of inorganic materials, for example, silicon oxide (SiOₓ), silicon nitride (SiNₓ), and silicon oxynitride (SiOₓN_{y}) are alternately stacked.

In the display area DPA, a first contact hole CNT1 and a second contact hole CNT2 penetrating the interlayer insulating layer IL to expose portions of the active layer ACT may be disposed, and a third contact hole CNT3 penetrating the interlayer insulating layer IL and the buffer layer BL to expose the bottom metal layer CAS may be disposed. In addition, a fourth contact hole CNT4 penetrating the interlayer insulating layer IL and the buffer layer BL to expose the first voltage wiring VL1 and a fifth contact hole CNT5 penetrating the interlayer insulating layer IL and the buffer layer BL to expose the second voltage wiring VL2 may be disposed. In the pad area PDA, a first pad contact hole CTP1 penetrating the interlayer insulating layer IL and the buffer layer BL to expose the first pad electrode PE1 may be disposed.

A third conductive layer 400 may be disposed on the interlayer insulating layer IL. The third conductive layer 400 may include a source electrode SE, a drain electrode DE, a first conductive pattern CDP1, and a second pad electrode PE2. The source electrode SE may electrically connect the active layer ACT and the bottom metal layer CAS through the first contact hole CNT1 and the third contact hole CNT3, and the drain electrode DE may electrically connect the active layer ACT and the first voltage wiring VL1 through the second contact hole CNT2 and the fourth contact hole CNT4. The first conductive pattern CDP1 may be electrically connected to the second voltage wiring VL2 through the fifth contact hole CNT5, and the second pad electrode PE2 may be electrically connected to the first pad electrode PE1 through the first pad contact hole CTP1. A passivation layer PV covering the third conductive layer 400 may be disposed on the third conductive layer 400, and a display element layer including a via layer VIA may be disposed.

In this embodiment, the second conductive layer 300 includes the gate electrode GE, and the third conductive layer 400 includes the source electrode SE, the drain electrode DE, the first conductive pattern CDP1, and the second pad electrode PE2. The above-described embodiment shown in FIGS. 5 through 22 is also applicable to circuit element layer having a different structure.

In concluding the detailed description, those skilled in the art will appreciate that many variations and modifications can be made to the embodiments described herein without substantially departing from the present disclosure. Therefore, the disclosed embodiments of the present disclosure are used in a generic and descriptive sense and not for purposes of limitation.

What is claimed is:

1. A display device comprising:
a substrate;
a via layer on the substrate;
a first electrode and a second electrode on the via layer and spaced apart from each other;
a first insulating layer on the first electrode and the second electrode;
a bank layer on the first insulating layer and having barrier portions and a bank portion having a greater thickness than the barrier portions;
a second insulating layer on the bank layer and the first insulating layer, the second insulating layer overlapping the barrier portions and not overlapping the bank portion;
light emitting elements on the second insulating layer and on the first electrode and the second electrode; and
a first connection electrode contacting an end of each light emitting element and a second connection electrode contacting another end of the light emitting elements.

2. The display device of claim 1, wherein the first insulating layer is directly on the via layer, the first electrode, and the second electrode.

3. The display device of claim 1, wherein a thickness of the first insulating layer is smaller than a thickness of the second insulating layer.

4. The display device of claim 3, wherein the thickness of the first insulating layer is in a range of 30% to 70% of the thickness of the second insulating layer.

5. The display device of claim 3, wherein the thickness of the first insulating layer is in a range of 500 Å to 3000 Å.

6. The display device of claim 1, wherein the first insulating layer and the second insulating layer contact each other at an area overlapping the light emitting elements.

7. The display device of claim 1, wherein the first insulating layer and the second insulating layer comprise the same material.

8. The display device of claim 1, wherein the barrier portions have a first barrier portion overlapping the first electrode and a second barrier portion spaced apart from the first barrier portion and overlapping the second electrode, and
wherein the bank portion extends around a periphery of the first barrier portion and the second barrier portion.

9. The display device of claim 8, wherein the bank layer has a first opening between the first barrier portion and the second barrier portion, and
wherein the light emitting elements are in the first opening.

10. The display device of claim 9, wherein the bank layer separates an emission area in which the light emitting elements are arranged from a sub-area spaced apart from the emission area,
wherein the bank layer has a second opening spaced apart from the first opening, and
wherein the first opening is in the emission area, and the second opening is disposed in the sub-area.

11. A display device comprising:
a substrate;
a via layer on the substrate;
a first electrode and a second electrode on the via layer and spaced apart from each other;
a first insulating layer on the via layer, the first electrode, and the second electrode;
a bank layer on the first insulating layer and separating an emission area and a sub-area spaced apart from the emission area;
a second insulating layer on the bank layer and the first insulating layer;
light emitting elements on the second insulating layer in the emission area and on the first electrode and the second electrode; and
a first connection electrode contacting an end of the light emitting elements and a second connection electrode contacting another end of the light emitting elements,
wherein the second insulating layer does not overlap areas other than the emission area and the sub-area.

12. The display device of claim 11, wherein the bank layer has barrier portions and a bank portion having a greater thickness than the barrier portions, and
wherein the barrier portions overlap the emission area, and the bank portion does not overlap the emission area and the sub-area.

13. The display device of claim 12, wherein the second insulating layer does not overlap the bank portion and overlaps the barrier portions.

14. The display device of claim 12, wherein the first insulating layer overlaps the bank portion and the barrier portions.

15. The display device of claim 12, wherein the barrier portions and the bank portion are integrally formed.

16. The display device of claim 11, wherein the first insulating layer and the second insulating layer contact each other at an area overlapping the light emitting elements.

17. The display device of claim 11, wherein a first contact portion and a second contact portion penetrate the first insulating layer and the second insulating layer, are spaced apart from each other, and are in the sub-area, and
wherein the first connection electrode is connected to the first electrode through the first contact portion, and the second connection electrode is connected to the second electrode through the second contact portion.

18. The display device of claim 11, further comprising:
a first conductive layer on the substrate and comprising a bottom metal layer, a first power line, a second power line, and a first pad electrode;
a semiconductor layer on the first conductive layer and comprising an active layer overlapping the bottom metal layer;
a second conductive layer on the semiconductor layer and comprising a source electrode contacting a portion of the semiconductor layer, a drain electrode contacting the first power line, a gate electrode overlapping the semiconductor layer, a first conductive pattern contacting the second power line, and a second pad electrode overlapping the first pad electrode; and
a third pad electrode on the second pad electrode.

19. The display device of claim 18, wherein the first electrode is electrically connected to the first power line through the source electrode, and the second electrode is electrically connected to the second power line through the first conductive pattern.

20. The display device of claim 18, wherein the first connection electrode, the second connection electrode, and the third pad electrode comprise the same material.
